(19) United States
(12) Patent Application Publication
(10) Pub. No.: US 2022/0204745 A1
(43) Pub. Date: Jun. 30, 2022

(54) COMPOSITION, PRODUCING METHOD OF COMPOSITION, CURED FILM, TRANSFER FILM, AND MANUFACTURING METHOD OF TOUCH PANEL

(71) Applicant: FUJIFILM Corporation, Tokyo (JP)

(72) Inventors: Yohei ARITOSHI, Fujinomiya-shi (JP); Kunihiko Kodama, Fujinomiya-shi (JP)

(73) Assignee: FUJIFILM Corporation, Tokyo (JP)

(21) Appl. No.: 17/699,387

(22) Filed: Mar. 21, 2022

Related U.S. Application Data
(63) Continuation of application No. PCT/JP2020/033105, filed on Sep. 1, 2020.

(30) Foreign Application Priority Data
Oct. 11, 2019 (JP) 2019-188207

(51) Int. Cl. C08L 33/02; G06F 3/044; C08K 5/17; C08K 3/22; C08K 7/18; C08K 5/3462; C08J 5/18

(52) U.S. Cl. CPC C08L 33/02; G06F 3/044; C08K 5/17; C08K 3/22; C08K 2003/2237; C08K 5/3462; C08J 5/18; G06F 2203/04103; C08K 2003/2244; C08K 7/18

(57) ABSTRACT

A composition contains an amine compound, metal oxide particles, and a binder polymer having an acid group, in which the amine compound has, as a substituent on a nitrogen atom in the amine compound, a substituent which includes a linking group having a linking chain length of 3 or more, and a weight-average molecular weight of the amine compound is 100 or more.

### CROSS-REFERENCE TO RELATED APPLICATIONS

This application is a Continuation of PCT International Application No. PCT/JP2020/033105 filed on Sep. 1, 2020, which claims priority under 35 U.S.C § 119(a) to Japanese Patent Application No. 2019-188207 filed on Oct. 11, 2019. Each of the above application(s) is hereby expressly incorporated by reference, in its entirety, into the present application.

### BACKGROUND OF THE INVENTION

### 1. Field of the Invention

The present invention relates to a composition, a producing method of a composition, a cured film, a transfer film, and a manufacturing method of a touch panel.

### 2. Description of the Related Art

A touch panel is often used as an input device in a display device of an electronic apparatus (for example, a mobile phone, a car navigation system, a personal computer, a ticket vending machine, a bank terminal, and the like).

It is known that such a touch panel is provided with a protective film for protecting electrodes including a metal wire.

For example, JP2014-056311A discloses a transfer material having a temporary support and a transparent curable resin layer laminated on the temporary support, in which a refractive index of the transparent curable resin layer at a wavelength of 550 nm is 1.55 or more.

### SUMMARY OF THE INVENTION

As a result of an examination of the transfer film disclosed in JP2014-056311A, the present inventors have found that bending the transfer film may cause cracks on a surface of the transparent curable resin layer. In particular, it has been found that, in a case where the transparent curable resin layer of the film disclosed in JP2014-056311A includes metal oxide particles, cracks are likely to occur due to bending.

An object to be achieved by the present invention is to provide a composition with which a transfer film having improved bendability is obtained in a case of having a layer including metal oxide particles. Another object to be achieved by the present invention is to provide a producing method of the composition, a cured film of the composition, a transfer film formed of the composition, and a manufacturing method of a touch panel using the composition.

As a result of intensive studies to achieve the above-described objects, the present inventors have found that, by using a composition that contains metal oxide particles and a binder polymer having an acid group and contains an amine compound which has a substituent including a linking group having a linking chain length in a specific range and has a weight-average molecular weight in a specific range, a transfer film having improved bendability is obtained in a case of having a layer including metal oxide particles.

JP2014-056311A does not disclose that an amine compound is contained in the transparent curable resin layer including metal oxide particles.

The configuration of the present invention and preferred aspects of the present invention, by which the above-described objects can be achieved, are as follows.

[1] A composition comprising:

an amine compound;

metal oxide particles; and

a binder polymer having an acid group,

in which the amine compound has, as a substituent on a nitrogen atom in the amine compound, a substituent which includes a linking group having a linking chain length of 3 or more, and

a weight-average molecular weight of the amine compound is 100 or more.

[2] The composition according to [1],

in which the amine compound is a compound represented by General Formula N.

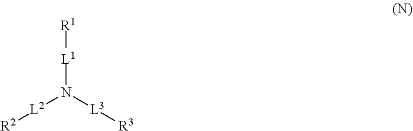

[3] The composition according to [1] or [2],

in which a content of the metal oxide particles is 40% to 95% by mass with respect to a total solid content of the composition.

[4] The composition according to any one of [1] to [3],

in which the metal oxide particles include at least one type selected from the group consisting of zirconium oxide particles and titanium oxide particles.

[5] The composition according to any one of [1] to [4], further comprising:

a compound having a 6-membered heterocyclic structure,

in which the compound having a 6-membered heterocyclic structure has a monocyclic or polycyclic aromatic heterocyclic ring structure.

[6] The composition according to [5],

in which the compound having a 6-membered heterocyclic structure has a 6-membered heterocyclic structure having two nitrogen atoms in the ring structure.

[7] The composition according to [5] or [6],

in which the compound having a 6-membered heterocyclic structure is adenine or pyrimidine.

[8] The composition according to any one of [1] to [7], further comprising:

an ethylenically unsaturated compound.

[9] The composition according to [8], further comprising:

a photopolymerization initiator.

[10] The composition according to [1], further comprising:

a compound having a 6-membered heterocyclic structure and an ethylenically unsaturated compound,

in which the compound having a 6-membered heterocyclic structure has a monocyclic or polycyclic aromatic heterocyclic ring structure,

the amine compound is a compound represented by General Formula N, and

the metal oxide particles include at least one type selected from the group consisting of zirconium oxide particles and titanium oxide particles,

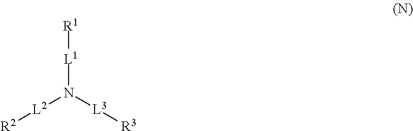

in General Formula N, L¹ represents a linking group having a linking chain length of 3 or more and including an oxygen atom, and R¹ represents a hydrogen atom or a halogen atom, and

L² and L³ each independently represent an alkylene group or a linking group having a linking chain length of 3 or more and including an oxygen atom, and R² and R³ each independently represent a hydrogen atom or a halogen atom.

[11] The composition according to any one of [1] to [10],

in which the composition is used for forming a protective film in a touch panel.

[12] The composition according to any one of [1] to [11],

in which the composition is used for forming a refractive index adjusting layer in a touch panel.

[13] A producing method of a composition comprising:

a step of preparing a composition using metal oxide particles, a binder polymer having an acid group, and an amine compound,

in which the amine compound has, as a substituent on a nitrogen atom in the amine compound, a substituent which includes a linking group having a linking chain length of 3 or more, and

a weight-average molecular weight of the amine compound is 100 or more.

[14] A cured film of the composition according to any one of [1] to [12].

[15] A transfer film comprising:

a temporary support; and

a refractive index adjusting layer including the composition according to any one of [1] to [12].

[16] The transfer film according to [15],

in which a refractive index of the refractive index adjusting layer is 1.55 to 1.80.

[17] The transfer film according to [15] or [16], further comprising:

a photosensitive resin layer between the temporary support and the refractive index adjusting layer.

[18] The transfer film according to [17],

in which the photosensitive resin layer contains a binder polymer, an ethylenically unsaturated compound, and a photopolymerization initiator.

[19] A manufacturing method of a touch panel, comprising:

a step of preparing a substrate for a touch panel having a structure in which at least one of an electrode for a touch panel or a wire for a touch panel is disposed on a substrate;

a step of forming a refractive index adjusting layer consisting of the composition according to any one of [1] to [12] or a refractive index adjusting layer obtained by drying the composition on a surface of the substrate for a touch panel, on a side on which at least one of the electrode for a touch panel or the wire for a touch panel is disposed;

a step of performing a pattern exposure on the refractive index adjusting layer formed on the substrate for a touch panel; and

a step of developing the refractive index adjusting layer subjected to the pattern exposure to obtain a cured film which protects at least a part of at least one of the electrode for a touch panel or the wire for a touch panel.

According to the present invention, it is possible to provide a composition with which a transfer film having improved bendability is obtained in a case of having a layer including metal oxide particles, a producing method of a composition, a cured film, a transfer film, and a manufacturing method of a touch panel.

### BRIEF DESCRIPTION OF THE DRAWINGS

FIG. 1 is a schematic cross-sectional view showing an example of a transfer film according to an embodiment of the present invention.

FIG. 2 is a schematic cross-sectional view showing a first specific example of a touch panel manufactured by using the transfer film according to the embodiment of the present invention.

FIG. 3 is a schematic cross-sectional view showing a second specific example of the touch panel manufactured by using the transfer film according to the embodiment of the present invention.

### DESCRIPTION OF THE PREFERRED EMBODIMENTS

Hereinafter, the content of the present disclosure will be described in detail. The configuration requirements will be described below based on the representative embodiments of the present disclosure, but the present disclosure is not limited to such embodiments.

In the present disclosure, a term “to” showing a range of numerical values is used as a meaning including a lower limit value and an upper limit value disclosed before and after the term.

In a range of numerical values described in stages in this specification, the upper limit value or the lower limit value described in one range of numerical values may be replaced with an upper limit value or a lower limit value of the range of numerical values described in other stages. In addition, in a range of numerical values described in this specification, the upper limit value or the lower limit value of the range of numerical values may be replaced with values shown in the examples.

Regarding a term, group (atomic group) of this present disclosure, a term with no description of “substituted” and “unsubstituted” includes both a group not including a substituent and a group including a substituent. For example, an “alkyl group” not only includes an alkyl group not including a substituent (unsubstituted alkyl group), but also an alkyl group including a substituent (substituted alkyl group).

In addition, in the present disclosure, “% by mass” is identical to “% by weight” and “part by mass” is identical to “part by weight”.

Further, in the present disclosure, a combination of two or more preferred aspects is the more preferred aspects.

In the present disclosure, in a case where a plurality of substances corresponding to components are present in a composition, an amount of each component in the composition means a total amount of the plurality of substances present in the composition, unless otherwise noted.

In the present disclosure, a term “step” not only includes an independent step, but also includes a step, in a case where the step may not be distinguished from the other step, as long as the expected object of the step is achieved.

In the present disclosure, “(meth)acrylic acid” has a concept including both acrylic acid and a methacrylic acid, “(meth)acrylate” has a concept including both acrylate and methacrylate, and “(meth)acryloyl group” has a concept including both acryloyl group and methacryloyl group.

A weight-average molecular weight (Mw) and a number average molecular weight (Mn) of the present disclosure, unless otherwise noted, are detected by a gel permeation chromatography (GPC) analysis apparatus using a column of TSKgel GMHxL, TSKgel G4000HxL, TSKgel G2000HxL (all product names manufactured by Tosoh Corporation), by using tetrahydrofuran (THF) as a solvent and a differential refractometer, and are molecular weights obtained by conversion using polystyrene as a standard substance.

In the present disclosure, unless otherwise specified, a molecular weight of a compound having a molecular weight distribution is the weight-average molecular weight.

In the present disclosure, unless otherwise specified, a ratio of constitutional units of a polymer is a molar ratio.

In the present disclosure, unless otherwise specified, a refractive index is a value at a wavelength of 550 nm measured at 25° C. with an ellipsometer.

Hereinafter, the present disclosure will be described in detail.

[Composition]

A composition according to an embodiment of the present invention contains an amine compound, metal oxide particles, and a binder polymer having an acid group, in which the amine compound has, as a substituent on a nitrogen atom in the amine compound, a substituent which includes a linking group having a linking chain length of 3 or more, and a weight-average molecular weight of the amine compound is 100 or more.

With the composition according to the embodiment of the present invention, a transfer film having improved bendability is obtained in a case of having a layer including metal oxide particles.

A reason for this is not clear in detail, but is presumed to be as follows by the present inventors.

By using metal oxide particles, a high refractive index can be imparted to a layer including the metal oxide particles, but the layer including the metal oxide particles is easily cracked. In the composition including the metal oxide particles, an amine compound which has a substituent including a linking group having a somewhat long linking chain length (for example, a chain-like group) and has a somewhat large weight-average molecular weight reacts with an acid group of a binder polymer having an acid group, and a part or all of the amine compounds are incorporated into the binder polymer. As a result, it is considered that a glass transition temperature (Tg) of the binder polymer is lowered, Tg of a film including the composition is lowered to be softened, and bendability is improved (difficult to crack).

In the composition according to the embodiment of the present invention, compared to other methods of lowering Tg of the binder polymer to be softened, a degree of freedom in formulation is higher, and in a preferred embodiment of the composition according to the embodiment of the present invention, rust preventive property can be further improved.

The composition according to the embodiment of the present invention can be used for any film formation on a touch panel, but in particular, the composition according to the embodiment of the present invention is preferably for forming a protective film and/or for forming a refractive index adjusting layer in a touch panel.

In a case where the composition according to the embodiment of the present invention is used for forming a protective film and for forming a refractive index adjusting layer in a touch panel, a single-layer refractive index adjusting layer formed of a cured product of the composition according to the embodiment of the present invention can be used as a protective film in the touch panel. In the case of being used for forming a protective film and for forming a refractive index adjusting layer in the touch panel, the composition according to the embodiment of the present invention preferably contains a binder polymer, an ethylenically unsaturated compound, and a photopolymerization initiator.

In a case where the composition according to the embodiment of the present invention is used for forming a refractive index adjusting layer in a touch panel, a layer including the composition according to the embodiment of the present invention or a layer of a cured product obtained by curing the composition according to the embodiment of the present invention can be used as the refractive index adjusting layer, and a separately prepared cured product of a photosensitive resin layer can be used as a protective film in the touch panel. In the case of being used for forming a refractive index adjusting layer in the touch panel, the composition according to the embodiment of the present invention may not contain a photopolymerization initiator, and may not contain a photopolymerization initiator and an ethylenically unsaturated compound.

Hereinafter, preferred compositions of the composition according to the embodiment of the present invention will be described. As necessary, the preferred composition of the composition according to the embodiment of the present invention will be described separately in the case where a single-layer refractive index adjusting layer formed of a cured product of the composition according to the embodiment of the present invention can be used as a protective film in a touch panel and the case where a cured product of the composition according to the embodiment of the present invention is used as a refractive index adjusting layer (that is, the case where a separately prepared cured product of a photosensitive resin layer can be used as a protective film in a touch panel).

[Amine Compound]

The amine compound used in the composition according to the embodiment of the present invention has, as a substituent on a nitrogen atom in the amine compound, a substituent which includes a linking group having a linking chain length of 3 or more, and has a weight-average molecular weight of 100 or more.

In the composition according to the embodiment of the present invention, the amine compound may not remain as an amine compound because all amounts thereof are reacted with acid groups of the binder polymer having an acid group. The composition according to the embodiment of the present invention also includes an aspect that the amine compound exists as a compound (including a salt) in which the amine compound is bonded with the binder polymer having an acid group, or a derivative such as an amine compound ion. In a case where the composition according to the embodiment of the present invention includes, in addition to the amine compound, a compound which reacts with the acid group of the binder polymer having an acid group (for example, ammonia), the binder polymer having an acid group may form a salt of both an ammonia salt and an amine compound salt.

In the present invention, the amine compound has, as a substituent on a nitrogen atom in the amine compound, a substituent which includes a linking group having a linking chain length of 3 or more. Among substituents of the nitrogen atom in the amine compound, at least one substituent may be the substituent which includes a linking group having a linking chain length of 3 or more. Here, the linking chain length means the number of atoms in a linking chain.

The substituent which includes a linking group having a linking chain length of 3 or more is preferably a substituent which includes a linking group having a linking chain length of 3 or more and including a heteroatom. Examples of the heteroatom include an oxygen atom, a sulfur atom, and a silicon atom, and an oxygen atom or a sulfur atom is preferable and an oxygen atom is more preferable. In a case where the linking group having a linking chain length of 3 or more has the heteroatom, the linking group may have the heteroatom at the terminal, or may have the heteroatom in the chain. In a case where the substituent which includes a linking group having a linking chain length of 3 or more has the heteroatom at the terminal of the linking group, it is preferable to have an —OH group or an —SH group, and from the viewpoint of increasing solubility in an aqueous solvent, it is more preferable to have an —OH group. In a case where the substituent which includes a linking group having a linking chain length of 3 or more has the heteroatom in the chain of the linking group, it is preferable to have an —O— bond or an —S— bond, and from the viewpoint of improving bendability and patterning properties, it is more preferable to have an —O— bond.

The substituent which includes a linking group having a linking chain length of 3 or more may be branched to have an additional substituent. The additional substituent is not particularly limited, examples thereof include a halogen atom, an alkyl group, and a hydroxy group, and an alkyl group or a hydroxy group is preferable.

The linking chain length of the linking group having a linking chain length of 3 or more is preferably 3 to 12, more preferably 3 to 10, particularly preferably 3 to 8, more particularly preferably 3 to 6, and still more preferably 4 to 6.

In a case where two or more nitrogen atoms are included in the amine compound, from a specific nitrogen atom in the amine compound as a starting point, the full-length linking chain length of a substituent including other nitrogen atoms is not used, only the linking chain length of the linking group between nitrogen atoms up to other nitrogen atoms is used (it is counted up to an atom which does not exceed other nitrogen atoms). For example, in a case of N,N,N′,N′-tetrakis(2-hydroxypropyl)ethylenediamine, it is assumed that the amine compound has four 2-hydroxypropyl groups having a linking chain length of 3 and one linking group having a linking chain length of 2 between nitrogen atoms. In a case of N,N,N′,N′-tetramethyl-1,6-hexanediamine, it is assumed that the amine compound has four methyl groups having a linking chain length of 1 and one linking group having a linking chain length of 6 between nitrogen atoms (it is not assumed that, from a nitrogen atom as a starting point, only four methyl groups having a linking chain length of 1 are counted).

On the other hand, in a case of N,N,N,N′,N′-tetramethylethylenediamine, it is assumed that the amine compound has four methyl groups having a linking chain length of 1 and one linking group having a linking chain length of 2 between nitrogen atoms, whereby it is outside the range of amine compounds specified in the present invention (from a nitrogen atom as a starting point, it is not counted as two methyl groups having a linking chain length of 1 and one substituent having a linking chain length of 4 including other nitrogen atoms).

The number of substituents of the nitrogen atom in the amine compound is not particularly limited, and may be 1, 2, or 3. That is, the amine compound may be any of a primary amine, a secondary amine, or a tertiary amine. From the viewpoint of crackability, the amine compound is preferably a secondary amine or a tertiary amine, and from the viewpoint of crackability, the amine compound is more preferably a tertiary amine.

In a case where the amine compound is a secondary amine or a tertiary amine, substituents of the nitrogen atoms may be the same or different from each other. In a case where the substituent on the nitrogen atom in the amine compound has two or more substituents which include a linking group having a linking chain length of 3 or more, it is preferable that the substituents are the same.

As the substituent on the nitrogen atom in the amine compound, the amine compound may have other substituents in addition to the substituent which includes a linking group having a linking chain length of 3 or more. Examples of the other substituents include an alkyl group and alkoxy group having a linking chain length of 2 or less, which may have an additional substituent. The additional substituent is not particularly limited, and examples thereof include a halogen atom, an alkyl group, and a hydroxy group. As the other substituents, an unsubstituted alkyl group having a linking chain length of 2 or less is preferable.

From the viewpoint of crackability, it is preferable that the substituents of the nitrogen atom in the amine compound are not bonded with each other to form a ring (that is, a chain-like structure is preferable). In addition, from the viewpoint of crackability, the substituent on the nitrogen atom in the amine compound is preferably a substituent having no ring structure.

In the present invention, it is preferable that the amine compound is a compound represented by General Formula N.

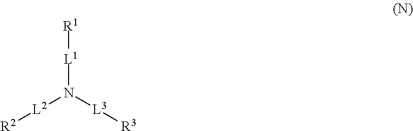

In General Formula N, L¹ represents a linking group having a linking chain length of 3 or more and including an oxygen atom, and R¹ represents a hydrogen atom or a halogen atom. L² and L³ each independently represent an alkylene group or a linking group having a linking chain length of 3 or more and including an oxygen atom, and R² and R³ each independently represent a hydrogen atom or a halogen atom.

In General Formula N, a preferred range of L¹ is the same as the preferred range of the linking group having a linking chain length of 3 or more.

In General Formula N, in a case where L² and L³ represent a linking group having a linking chain length of 3 or more and including an oxygen atom, it is preferable that the linking group is the same as the linking group having a linking chain length of 3 or more and including an oxygen atom, which is represented by L¹. In a case where L² and L³ represent an alkylene group, an alkylene group having 1 or 2 carbon atoms is preferable.

In General Formula N, R¹ to R³ are preferably hydrogen atoms.

Specific examples of the amine compound include 3-(diethylamino)-1,2-propanediol, N-methyldiethanolamine, 2-[2-(dimethylamino)ethoxy]ethanol, N,N,N′,N′-tetrakis(2-hydroxypropyl)ethylenediamine, tri-n-propylamine, triisopropylamine, tri-n-butylamine, tris(2-ethylhexyl)amine, N,N-dimethyl n-propylamine, N,N-dimethylisopropylamine, N,N-dimethyldodecylamine, N,N,N′,N′-tetramethyl-1,3-propanediamine, N,N-dimethyl-N′,N′-dimethyl-1,3-propanediamine, N,N-dibutylethanolamine, bis(2-dimethylaminoethyl)ether, and N,N,N′,N′-tetramethyl-1,6-hexanediamine. Among these, 3-(diethylamino)-1,2-propanediol, N-methyldiethanolamine, 2-[2-(dimethylamino)ethoxy]ethanol, or N,N,N′,N′-tetrakis(2-hydroxypropyl)ethylenediamine is preferable, and from the viewpoint of improving crackability, 3-(diethylamino)-1,2-propanediol, N-methyldiethanolamine, or 2-[2-(dimethylamino)ethoxy]ethanol is more preferable.

In the present invention, a weight-average molecular weight of the amine compound is 100 or more. The upper limit of the weight-average molecular weight of the amine compound is not particularly limited, and may be, for example, 500 or less. From the viewpoint of crackability, the weight-average molecular weight of the amine compound is preferably 100 to 350, and from the viewpoint of further improving the crackability, the weight-average molecular weight thereof is preferably 110 to 250, particularly preferably 120 to 200, and more particularly preferably 130 to 150.

One kind of the amine compound may be used singly, or two or more kinds thereof may be used in combination.

From the viewpoint of crackability, a content of the amine compound is preferably 0.1% by mass or more, more preferably 0.5% by mass or more, and still more preferably 1.0% by mass or more with respect to a total solid content of the composition according to the embodiment of the present invention. In addition, the content of the amine compound is preferably 10% by mass or less and more preferably 5% by mass or less with respect to a total solid content of the photosensitive resin composition of the present invention.

From the viewpoint of crackability, the content of the amine compound is preferably 5% by mass or more and more preferably 10% by mass or more with respect to a total solid content of the binder polymer having an acid group. From the viewpoint of rust preventive property, the content of the amine compound is preferably 35% by mass or less and more preferably 25% by mass or less with respect to a total solid content of the binder polymer having an acid group.

The total solid content in the composition of the present disclosure refers to an amount excluding volatile components such as a solvent, and it is not necessary that the solid content in the present disclosure is a solid, and the solid content may be a liquid or a mixture of a solid and a liquid.

[Metal Oxide Particles]

The type of the metal oxide particles is not particularly limited, and known metal oxide particles can be used.

A metal of the metal oxide particles also includes semimetal such as B, Si, Ge, As, Sb, or Te.

Specifically, as the metal oxide particles, at least one selected from the group consisting of tin oxide particles, zirconium oxide particles (ZrO₂ particles), Nb₂O₅ particles, titanium oxide particles (TiO₂ particles), or silicon dioxide particles (SiO₂ particles) is preferable.

Among these, from the viewpoint that it is easy to adjust a refractive index of the refractive index adjusting layer to 1.6 or more, it is more preferable that the metal oxide particles include at least one selected from the group consisting of zirconium oxide particles and titanium oxide particles.

Examples of a preferred combination of the metal oxide particles include zirconium oxide particles and tin oxide particles, zirconium oxide particles and silicon oxide particles, and titanium oxide particles and tin oxide particles.

The metal oxide particles may be alloy oxides, and specific examples thereof include oxide particles of an alloy of zirconium and tin, oxide particles of an alloy of zirconium and silicon, and oxide particles of an alloy of titanium and tin.

From the viewpoint of transparency of a cured film, for example, an average primary particle diameter of the metal oxide particles is preferably 1 nm to 200 nm and more preferably 3 nm to 80 nm.

The average primary particle diameter of the metal oxide particles is calculated by measuring particle diameters of 200 random metal oxide particles using an electron microscope and arithmetically averaging the measurement result. In a case where a shape of the metal oxide particle is not a spherical shape, the longest side is set as the particle diameter.

The composition according to the embodiment of the present invention may include only one kind of the metal oxide particles or two or more kinds thereof.

From the viewpoint that covering property of a concealed object such as an electrode pattern is improved and visibility of the concealed object can be effectively improved, a content of the metal oxide particles is preferably 40% by mass to 95% by mass, more preferably 40% by mass to 90% by mass, and still more preferably 40% by mass to 85% by mass with respect to the total solid content of the composition according to the embodiment of the present invention.

In a case of using zirconium oxide particles or titanium oxide particles as the metal oxide particles, a content of the zirconium oxide particles or titanium oxide particles is preferably 40% by mass to 95% by mass, more preferably 40% by mass to 90% by mass, and still more preferably 40% by mass to 85% by mass with respect to a total mass of the refractive index adjusting layer.

Examples of a commercially available product of the metal oxide particles include calcined zirconium oxide particles (manufactured by CIK-Nano Tek., product name: ZRPGM15WT %-F04), calcined zirconium oxide particles (manufactured by CIK-Nano Tek., product name: ZRPGM15WT %-F74), calcined zirconium oxide particles (manufactured by CIK-Nano Tek., product name: ZRPGM15WT %-F75), calcined zirconium oxide particles (manufactured by CIK-Nano Tek., product name: ZRPGM15WT %-F76), zirconium oxide particles (NanoUse OZ-S30M, manufactured by Nissan Chemical Corporation), and zirconium oxide particles (NanoUse OZ-S30K, manufactured by Nissan Chemical Corporation).

[Binder Polymer Having Acid Group]

<Type of Binder Polymer Having Acid Group>

The binder polymer having an acid group (hereinafter, also simply referred to as a binder polymer) is preferably an alkali-soluble resin.

From the viewpoint of developability, for example, the binder polymer is preferably a binder polymer having an acid value of 30 to 200 mgKOH/g and more preferably an alkali-soluble resin having an acid value of 30 to 200 mgKOH/g.

In the present disclosure, the “alkali-soluble” means that the solubility in an aqueous solution of 1% by mass sodium carbonate at 22° C. is 0.1% by mass or more.

In addition, the acid value of the binder polymer is a value measured according to the method described in JIS K0070: 1992.

In addition, from the viewpoint that it is easy to form a strong film by thermally crosslinking with a crosslinking component by heating, for example, the binder polymer is still more preferably a resin (so-called a carboxy group-containing resin) having an acid value of 30 to 160 mgKOH/g and having a carboxy group, and particularly preferably an acrylic resin (so-called a carboxy group-containing acrylic resin) having an acid value of 30 to 160 mgKOH/g or more and having a carboxy group.

In the present disclosure, the acrylic resin refers to a resin having a constitutional unit derived from a (meth)acrylic compound, and a content of the constitutional unit is preferably 30% by mass or more and more preferably 50% by mass or more with respect to a total mass of the resin.

From the viewpoint of water vapor permeability and bendability of a cured film to be obtained and pressure-sensitive adhesiveness of an uncured film to be obtained, the binder polymer is preferably an acrylic resin or a styrene-acrylic copolymer.

In the present disclosure, the styrene-acrylic copolymer refers to a resin having a constitutional unit derived from a styrene compound and a constitutional unit derived from a (meth)acrylic compound, and a total content of the constitutional unit derived from a styrene compound and the constitutional unit derived from a (meth)acrylic compound is preferably 30% by mass or more and more preferably 50% by mass or more with respect to the total mass of the copolymer.

In addition, the content of the constitutional unit derived from a styrene compound is preferably 1% by mass or more, more preferably 5% by mass or more, and still more preferably 5% by mass to 80% by mass with respect to the total mass of the above-described copolymer.

In addition, the content of the constitutional unit derived from a (meth)acrylic compound is preferably 5% by mass or more, more preferably 10% by mass or more, and still more preferably 20% by mass to 95% by mass with respect to the total mass of the above-described copolymer.

Further, examples of the above-described (meth)acrylic compound include a (meth)acrylate compound, a (meth)acrylic acid, a (meth)acrylamide compound, and a (meth)acrylonitrile. Among these, at least one compound selected from the group consisting of a (meth)acrylate compound and a (meth)acrylic acid is preferable.

—Constitutional Unit Having Aromatic Ring—

From the viewpoint of water vapor permeability and hardness of the cured film to be obtained, the binder polymer preferably has a constitutional unit having an aromatic ring.

Examples of a monomer forming the constitutional unit having an aromatic ring include styrene, tert-butoxystyrene, methylstyrene, α-methylstyrene, and benzyl (meth)acrylate.

Among these, a styrene compound is preferable, and styrene is particularly preferable.

In addition, from the viewpoint of water vapor permeability and hardness of the cured film to be obtained, the binder polymer more preferably has a constitutional unit (constitutional unit derived from styrene) represented by Formula (S).

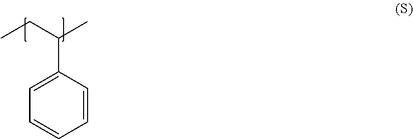

In a case where the binder polymer includes the constitutional unit having an aromatic ring, from the viewpoint of water vapor permeability and hardness of the cured film to be obtained, a content of the constitutional unit having an aromatic ring is preferably 5% by mass to 90% by mass, more preferably 10% by mass to 70% by mass, and particularly preferably 20% by mass to 50% by mass with respect to the total mass of the binder polymer.

In addition, from the viewpoint of water vapor permeability and hardness of the cured film to be obtained, the content of the constitutional unit having an aromatic ring in the binder polymer is preferably 5 mol % to 70 mol %, more preferably 10 mol % to 60 mol %, and particularly preferably 20 mol % to 50 mol % with respect to the total amount of the binder polymer.

Further, from the viewpoint of water vapor permeability and hardness of the cured film to be obtained, the content of the constitutional unit represented by Formula (S) in the binder polymer is preferably 5 mol % to 70 mol %, more preferably 10 mol % to 60 mol %, and particularly preferably 20 mol % to 50 mol % with respect to the total amount of the binder polymer.

In the present disclosure, in a case where the content of a “constitutional unit” is defined by a molar ratio, the “constitutional unit” is synonymous with a “monomer unit”. In addition, in the present disclosure, the “monomer unit” may be modified after polymerization by a polymer reaction or the like. The same applies to the following.

—Constitutional Unit Having Aliphatic Hydrocarbon Ring—

From the viewpoint of hardness of the cured film to be obtained and pressure-sensitive adhesiveness of the uncured film to be obtained, the binder polymer preferably has a constitutional unit having an aliphatic hydrocarbon ring.

Examples of the aliphatic hydrocarbon ring in the constitutional unit having an aliphatic hydrocarbon ring include a tricyclodecane ring, a cyclohexane ring, a cyclopentane ring, a norbornane ring, and an isophorone ring.

Among these, from the viewpoint of hardness of the cured film to be obtained and pressure-sensitive adhesiveness of the uncured film to be obtained, a ring in which two or more aliphatic hydrocarbon rings are fused is preferable, and a tetrahydrodicyclopentadiene ring (tricyclo[5.2.1.0^{2,6}]decane ring) is particularly preferable.

Examples of a monomer forming the constitutional unit having an aliphatic hydrocarbon ring include dicyclopentanyl (meth)acrylate, cyclohexyl (meth)acrylate, and isobornyl (meth)acrylate.

In addition, from the viewpoint of hardness of the cured film to be obtained and pressure-sensitive adhesiveness of the uncured film to be obtained, the binder polymer more preferably has a constitutional unit represented by Formula (Cy), and particularly preferably has the constitutional unit represented by Formula (S) and the constitutional unit represented by Formula (Cy).

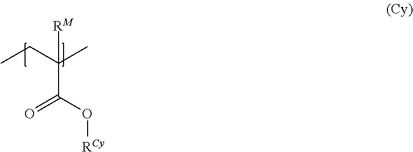

In Formula (Cy), R^{M} represents a hydrogen atom or a methyl group, and RC represents a monovalent group having an aliphatic hydrocarbon ring structure.

R^{M} in Formula (Cy) is preferably a methyl group.

From the viewpoint of hardness of the cured film to be obtained and pressure-sensitive adhesiveness of the uncured film to be obtained, R^{Cy} in Formula (Cy) is preferably a monovalent group having an aliphatic hydrocarbon ring structure having 5 to 20 carbon atoms, more preferably a monovalent group having an aliphatic hydrocarbon ring structure having 6 to 16 carbon atoms, and particularly preferably a monovalent group having an aliphatic hydrocarbon ring structure having 8 to 14 carbon atoms.

In addition, from the viewpoint of hardness of the cured film to be obtained and pressure-sensitive adhesiveness of the uncured film to be obtained, the aliphatic hydrocarbon ring structure in R^{Cy} of Formula (Cy) is preferably a cyclopentane ring structure, a cyclohexane ring structure, a tetrahydrodicyclopentadiene ring structure, a norbornane ring structure, or an isophorone ring structure, more preferably a cyclohexane ring structure or a tetrahydrodicyclopentadiene ring structure, and particularly preferably a tetrahydrodicyclopentadiene ring structure.

Further, from the viewpoint of hardness of the cured film to be obtained and pressure-sensitive adhesiveness of the uncured film to be obtained, the aliphatic hydrocarbon ring structure in R^{Cy} of Formula (Cy) is preferably a ring structure in which two or more aliphatic hydrocarbon rings are fused, and more preferably a ring in which two to four aliphatic hydrocarbon rings are fused.

Furthermore, from the viewpoint of hardness of the cured film to be obtained and pressure-sensitive adhesiveness of the uncured film to be obtained, RC in Formula (Cy) is preferably a group in which the oxygen atom in —C(═O)O— of Formula (Cy) and the aliphatic hydrocarbon ring structure are directly bonded, that is, an aliphatic hydrocarbon ring group, more preferably a cyclohexyl group or a dicyclopentanyl group, and particularly preferably a dicyclopentanyl group.

The binder polymer may have one constitutional unit having an aliphatic hydrocarbon ring alone, or two or more kinds thereof.

In a case where the binder polymer includes the constitutional unit having an aliphatic hydrocarbon ring, from the viewpoint of water vapor permeability and hardness of the cured film to be obtained, a content of the constitutional unit having an aliphatic hydrocarbon ring is preferably 5% by mass to 90% by mass, more preferably 10% by mass to 80% by mass, and particularly preferably 20% by mass to 70% by mass with respect to the total mass of the binder polymer.

In addition, from the viewpoint of water vapor permeability and hardness of the cured film to be obtained, the content of the constitutional unit having an aliphatic hydrocarbon ring in the binder polymer is preferably 5 mol % to 70 mol %, more preferably 10 mol % to 60 mol %, and particularly preferably 20 mol % to 50 mol % with respect to the total amount of the binder polymer.

Further, from the viewpoint of water vapor permeability and hardness of the cured film to be obtained, the content of the constitutional unit represented by Formula (Cy) in the binder polymer is preferably 5 mol % to 70 mol %, more preferably 10 mol % to 60 mol %, and particularly preferably 20 mol % to 50 mol % with respect to the total amount of the binder polymer.

In a case where the binder polymer includes the constitutional unit having an aromatic ring and the constitutional unit having an aliphatic hydrocarbon ring, from the viewpoint of water vapor permeability, bendability, and hardness of the cured film to be obtained, the total content of the constitutional unit having an aromatic ring and the constitutional unit having an aliphatic hydrocarbon ring is preferably 10% by mass to 90% by mass, more preferably 20% by mass to 80% by mass, and particularly preferably 40% by mass to 75% by mass with respect to the total mass of the binder polymer.

In addition, from the viewpoint of water vapor permeability, bendability, and hardness of the cured film to be obtained, the total content of the constitutional unit having an aromatic ring and the constitutional unit having an aliphatic hydrocarbon ring in the binder polymer is preferably 10 mol % to 80 mol %, more preferably 20 mol % to 70 mol %, and particularly preferably 40 mol % to 60 mol % with respect to the total amount of the binder polymer.

Further, from the viewpoint of water vapor permeability, bendability, and hardness of the cured film to be obtained, the total content of the constitutional unit represented by Formula (S) and the constitutional unit represented by Formula (Cy) in the binder polymer is preferably 10 mol % to 80 mol %, more preferably 20 mol % to 70 mol %, and particularly preferably 40 mol % to 60 mol % with respect to the total amount of the binder polymer.

In addition, from the viewpoint of water vapor permeability, bendability, and hardness of the cured film to be obtained, the molar amount nS of the constitutional unit represented by Formula (S) and the molar amount nCy of the constitutional unit represented by Formula (Cy) in the binder polymer preferably satisfy the relationship shown in the following expression (SCy), more preferably satisfy the following expression (SCy-1), and particularly preferably satisfy the following expression (SCy-2).

0.2≤nS/(nS+nCy)≤0.8 Expression (SCy)

0.30≤nS/(nS+nCy)≤0.75 Expression (SCy-1)

0.40≤nS/(nS+nCy)≤0.70 Expression (SCy-2)

—Constitutional Unit Having Acid Group—

From the viewpoint of hardness of the cured film to be obtained, and developability, the binder polymer having an acid group has a constitutional unit having an acid group.

Examples of the above-described acid group include a carboxy group, a sulfo group, a phosphonic acid group, and a phosphoric acid group, and a carboxy group is preferable.

Preferred examples of the above-described constitutional unit having an acid group include constitutional units derived from (meth)acrylic acid, which are shown below, and more preferred examples thereof include a constitutional unit derived from methacrylic acid.

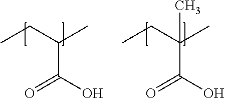

The binder polymer may have one constitutional unit having an acid group alone, or two or more kinds thereof.

In a case where the binder polymer includes the constitutional unit having an acid group, from the viewpoint of hardness of the cured film to be obtained, and developability, the content of the constitutional unit having an acid group is preferably 5% by mass to 50% by mass, more preferably 5% by mass to 40% by mass, and particularly preferably 10% by mass to 30% by mass with respect to the total mass of the binder polymer.

In addition, from the viewpoint of hardness of the cured film to be obtained, and developability, the content of the constitutional unit having an acid group in the binder polymer is preferably 5 mol % to 70 mol %, more preferably 10 mol % to 50 mol %, and particularly preferably 15 mol % to 30 mol % with respect to the total amount of the binder polymer.

Further, from the viewpoint of hardness of the cured film to be obtained, and developability, the content of the constitutional unit derived from (meth)acrylic acid in the binder polymer is preferably 5 mol % to 70 mol %, more preferably 10 mol % to 50 mol %, and particularly preferably 10 mol % to 30 mol % with respect to the total amount of the binder polymer.

—Constitutional Unit Having Reactive Group—

From the viewpoint of hardness of the cured film to be obtained and pressure-sensitive adhesiveness of the uncured film to be obtained, the binder polymer preferably has a reactive group, and more preferably has a constitutional unit having a reactive group.

As the reactive group, a radically polymerizable group is preferable, and an ethylenically unsaturated bond-containing group is more preferable. In addition, in a case where the binder polymer has an ethylenically unsaturated bond-containing group, the binder polymer preferably has a constitutional unit having an ethylenically unsaturated bond-containing group in a side chain.

In the present disclosure, a “main chain” represents a relatively longest binding chain in a molecule of a polymer compound constituting a resin, and a “side chain” represents an atomic group branched from the main chain.

As the ethylenically unsaturated bond-containing group, an allyl group, a (meth)acryloyl group, or a (meth)acryloyloxy group is preferable, an allyl group or a (meth)acryloyloxy group is more preferable, and an allyl group is particularly preferable.

Examples of the constitutional unit having a reactive group include those shown below, but it is needless to say that the constitutional unit having a reactive group is not limited thereto.

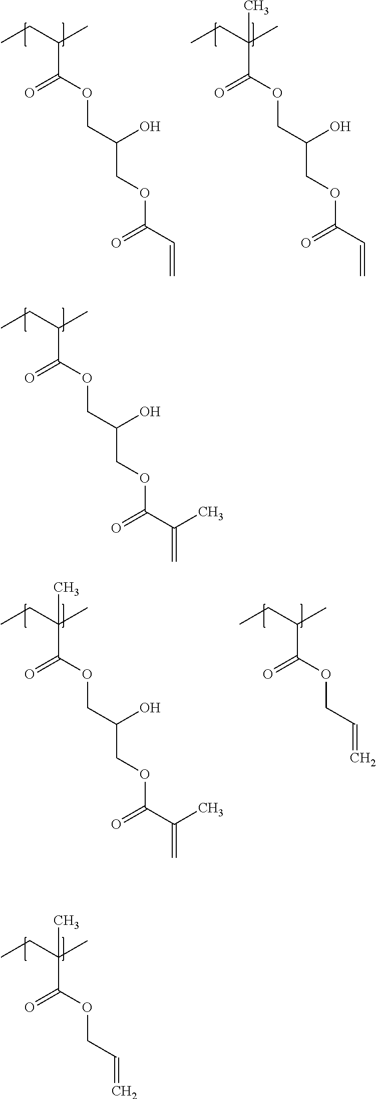

The binder polymer may have one constitutional unit having a reactive group alone, or two or more kinds thereof.

In a case where the binder polymer includes the constitutional unit having a reactive group, from the viewpoint of hardness of the cured film to be obtained and pressure-sensitive adhesiveness of the uncured film to be obtained, the content of the constitutional unit having a reactive group is preferably 5% by mass to 95% by mass, more preferably 10% by mass to 90% by mass, and particularly preferably 70% by mass to 90% by mass with respect to the total mass of the binder polymer.

In addition, from the viewpoint of hardness of the cured film to be obtained and pressure-sensitive adhesiveness of the uncured film to be obtained, the content of the constitutional unit having a reactive group in the binder polymer is preferably 5 mol % to 95 mol %, more preferably 10 mol % to 90 mol %, and particularly preferably 70 mol % to 85 mol % with respect to the total amount of the binder polymer.

Examples of a method for introducing the reactive group into the binder polymer include a method of reacting an epoxy compound, a blocked isocyanate compound, an isocyanate compound, a vinyl sulfone compound, an aldehyde compound, a methylol compound, a carboxylic acid anhydride, or the like with a hydroxy group, a carboxy group, a primary amino group, a secondary amino group, an acetoacetyl group, a sulfo group, or the like.

Preferred examples of the method for introducing the reactive group into the binder polymer include a method in which a polymer having a carboxy group is synthesized by a polymerization reaction, and then a glycidyl (meth)acrylate is reacted with a part of the carboxy group of the obtained polymer by a polymer reaction, thereby introducing a (meth)acryloxy group into the polymer. By this method, a binder polymer having a (meth)acryloxy group in the side chain can be obtained.

The above-described polymerization reaction is preferably carried out under a temperature condition of 70° C. to 100° C., and more preferably carried out under a temperature condition of 80° C. to 90° C. As a polymerization initiator used in the above-described polymerization reaction, an azo-based initiator is preferable, and for example, V-601 (product name) or V-65 (product name) manufactured by FUJIFILM Wako Pure Chemical Corporation is more preferable. The above-described polymer reaction is preferably carried out under a temperature condition of 80° C. to 110° C. In the above-described polymer reaction, it is preferable to use a catalyst such as an ammonium salt.

—Specific Examples of Binder Polymer Having Acid Group—

Specific examples of the binder polymer having an acid group include ZB-015M (manufactured by FUJIFILM Fine Chemicals Co., Ltd.) and ARUFON UC3920 (manufactured by Toagosei Co., Ltd.).

Preferred examples of the binder polymer having an acid group include the following polymers. Content ratios (a to d), weight-average molecular weight Mw, and the like of each of the constitutional units shown below can be appropriately changed according to the purpose.

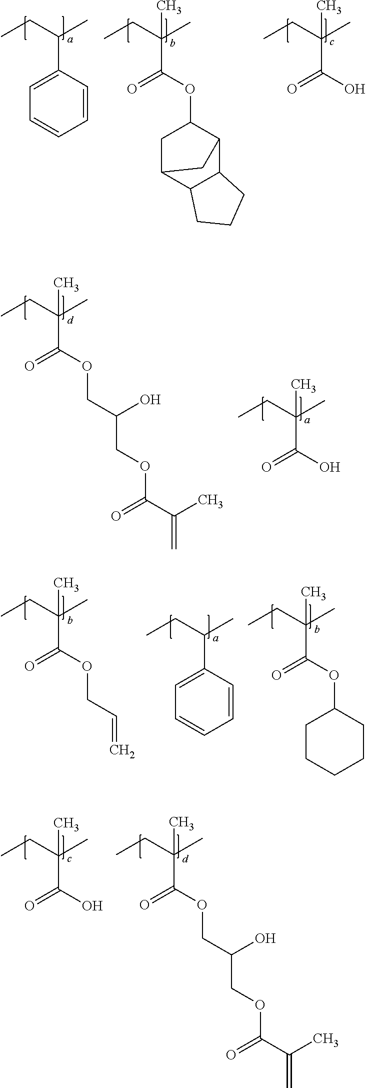

<Weight-Average Molecular Weight of Binder Polymer Having Acid Group>

From the viewpoint of hardness of the cured film to be obtained and pressure-sensitive adhesiveness of the uncured film to be obtained, a weight-average molecular weight (Mw) of the binder polymer having an acid group is preferably 5,000 or more, more preferably 10,000 or more, still more preferably 10,000 to 50,000, and particularly preferably 20,000 to 30,000.

<Content of Binder Polymer Having Acid Group>

The composition according to the embodiment of the present invention may include only one kind of the binder polymer having an acid group, or may include two or more kinds thereof.

In the case where a single-layer refractive index adjusting layer formed of a cured product of the composition according to the embodiment of the present invention can be used as a protective film in a touch panel, for example, from the viewpoint of hardness of the cured film and handleability of a transfer film, the content of the binder polymer having an acid group is preferably 5% by mass to 50% by mass, more preferably 20% by mass to 40% by mass, and still more preferably 25% by mass to 35% by mass with respect to the total solid content of the composition according to the embodiment of the present invention.

In the case where a cured product of the composition according to the embodiment of the present invention is used as a refractive index adjusting layer and a cured product of a photosensitive resin layer is used as a protective film in a touch panel, the content of the binder polymer having an acid group is preferably 5% by mass to 50% by mass, more preferably 10% by mass to 40% by mass, and still more preferably 12% by mass to 35% by mass with respect to the total solid content of the composition according to the embodiment of the present invention.

[Residual Monomer]

From the viewpoint of improving patterning properties, a content of a residual monomer of each constitutional unit in the binder polymer is preferably 5,000 ppm by mass or less, more preferably 2,000 ppm by mass or less, and still more preferably 500 ppm by mass or less with respect to the total mass of the binder polymer. The lower limit is not particularly limited, but is preferably 1 ppm by mass or more and more preferably 10 ppm by mass or more.

From the viewpoint of patterning properties and reliability, the residual monomer of each constitutional unit in the binder polymer is preferably 3,000 ppm by mass or less, more preferably 600 ppm by mass or less, and still more preferably 100 ppm by mass or less with respect to the total mass of the photosensitive composition layer. The lower limit is not particularly limited, but is preferably 0.1 ppm by mass or more and more preferably 1 ppm by mass or more.

It is preferable that the amount of residual monomer of the monomer in a case of synthesizing the binder polymer by the polymer reaction is also within the above-described range. For example, in a case where glycidyl acrylate is reacted with a side chain of carboxylic acid to synthesize the binder polymer, the content of glycidyl acrylate is preferably within the above-described range.

The amount of residual monomers can be measured by a known method such as liquid chromatography and gas chromatography.

[Compound Having 6-Membered Heterocyclic Structure]

From the viewpoint of improving bendability and rust preventive property, the composition according to the embodiment of the present invention preferably further contains a compound having a 6-membered heterocyclic structure.

In the present invention, it is preferable that the compound having a 6-membered heterocyclic structure has a monocyclic or polycyclic aromatic heterocyclic ring structure.

As the above-described heterocyclic structure included in the compound having a 6-membered heterocyclic structure, from the viewpoint of development residue inhibitory property and rust preventive property, it is preferable to have at least one atom of a nitrogen atom or a sulfur atom in the ring structure (also referred to as “have as a ring member in the present disclosure), it is more preferable to have a nitrogen atom in the ring structure, it is still more preferably to have one or two nitrogen atoms in the ring structure, and it is particularly preferable to have two nitrogen atoms in the ring structure.

Further, as the above-described heterocyclic structure, from the viewpoint of development residue inhibitory property and rust preventive property, the compound having a 6-membered heterocyclic structure preferably has a 6-membered heterocyclic structure having a nitrogen atom in the ring structure. In the present invention, it is more preferable that the compound having a 6-membered heterocyclic structure has a 6-membered heterocyclic structure having two nitrogen atoms in the ring structure.

In addition, the above-described heterocyclic structure included in the compound having a 6-membered heterocyclic structure may be an aliphatic heterocyclic structure or an aromatic heterocyclic structure, and may be a monocyclic heterocyclic structure or a polycyclic structure in which at least one heterocycle is condensed. However, from the viewpoint of volatility and rust preventive property, the above-described heterocyclic structure is preferably an aromatic heterocyclic structure, and more preferably a monocyclic or bicyclic aromatic heterocyclic structure.

Further, the compound having a 6-membered heterocyclic structure may have only one of the above-described heterocyclic structure or two or more thereof, but from the viewpoint of development residue inhibitory property, volatility, and rust preventive property, it is preferable to have only one of the above-described heterocyclic structure.

Specific examples of the above-described heterocyclic structure included in the compound having a 6-membered heterocyclic structure include a pyridine ring structure, a pyrimidine ring structure, a 1,3,5-triazine ring structure, a quinoline ring structure, an isoquinoline ring structure, a phthalazine ring structure, a naphthylidine ring structure, a quinoxaline ring structure, a quinazoline ring structure, a cinnoline ring structure, a purine ring structure, a phenanthridine ring structure, and an acridine ring structure.

Among these, from the viewpoint of development residue inhibitory property, volatility, and rust preventive property, a pyridine ring structure, a pyrimidine ring structure, a 1,3,5-triazine ring structure, or a purine ring structure is preferable, and a pyridine ring structure or a purine ring structure is more preferable.

The compound having a 6-membered heterocyclic structure preferably has a heterocyclic structure having at least one atom of an oxygen atom, a nitrogen atom, or a sulfur atom in the ring structure, and has at least one functional group selected from the group consisting of —SH, —OH, —COOH, —NH₂, and —CONH₂.

In the compound having a 6-membered heterocyclic structure, from the viewpoint of development residue inhibitory property and rust preventive property, the above-described functional group is preferably a group directly bonded to a heterocycle in the above-described heterocyclic structure.

As the above-described functional group included in the compound having a 6-membered heterocyclic structure, from the viewpoint of development residue inhibitory property, adsorptivity to the wire, and rust preventive property, at least one group selected from the group consisting of —SH, —OH, —COOH, —NH₂, and —CONH₂ is preferable, at least one group selected from the group consisting of —OH and —COOH is more preferable, and —COOH is particularly preferable.

From the viewpoint of development residue inhibitory property and rust preventive property, the compound having a 6-membered heterocyclic structure is preferably a compound having a total of 1 to 3 of the above-described functional groups selected from the group consisting of —SH, —OH, —COOH, —NH₂, and —CONH₂, more preferably a compound having a total of 1 or 2 of the above-described functional groups selected from the group consisting of —SH, —OH, —COOH, —NH₂, and —CONH₂, and particularly preferably a compound having one functional group selected from the group consisting of —SH, —OH, —COOH, —NH₂, and —CONH₂.

In addition, from the viewpoint of development residue inhibitory property, adsorptivity to the wire, volatility, and rust preventive property, the compound having a 6-membered heterocyclic structure is preferably a compound having at least one functional group selected from the group consisting of —OH and —COOH, more preferably a compound having one or two functional groups selected from the group consisting of —OH and —COOH, and particularly preferably a compound having, as the above-described functional group, one —COOH.

From the viewpoint of volatility and rust preventive property, a molecular weight of the compound having a 6-membered heterocyclic structure is preferably 500 or less, more preferably 80 to 300, still more preferably 100 to 200, and particularly preferably 100 to 150.

In a case where the compound having a 6-membered heterocyclic structure is a compound having a pyridine ring structure, a pyrimidine ring structure, or a 1,3,5-triazine ring structure, from the viewpoint of development residue inhibitory property and rust preventive property, the compound having a 6-membered heterocyclic structure is preferably a compound represented by any one of Formula (A-1), Formula (A-2), or Formula (A-3), and more preferably a compound represented by Formula (A-2), which corresponds to the compound having a pyrimidine ring structure.

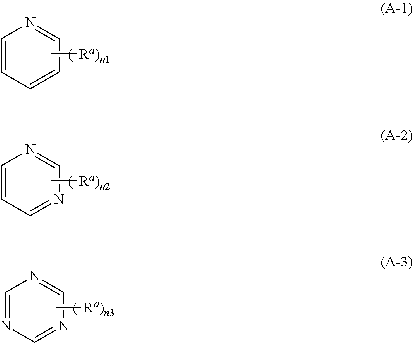

In Formulae (A-1) to (A-3), R^{a}'s each independently represent —SH, —OH, —COOH, or —NH₂, n1 represents an integer of 0 to 5, n2 represents an integer of 0 to 4, and n3 represents an integer of 0 to 3.

In Formulae (A-1) to (A-3), from the viewpoint of development residue inhibitory property, adsorptivity to the wire, and rust preventive property, R^{a} is preferably —SH, —OH, or —COOH, more preferably —OH or —COOH, and particularly preferably —COOH.

From the viewpoint of development residue inhibitory property, adsorptivity to the wire, volatility, and rust preventive property, n1 in Formula (A-1) is preferably an integer of 1 to 3, more preferably 1 or 2, and particularly preferably 1.

From the viewpoint of development residue inhibitory property, adsorptivity to the wire, volatility, and rust preventive property, n2 in Formula (A-2) is preferably an integer of 0 to 3 and more preferably 0.

From the viewpoint of development residue inhibitory property and rust preventive property, n3 in Formula (A-3) is preferably 1 or 3 and more preferably 1.

In a case where the compound having a 6-membered heterocyclic structure is a compound having a purine ring structure, from the viewpoint of rust preventive property, the compound having a 6-membered heterocyclic structure is preferably adenine.

The compound having a 6-membered heterocyclic structure is not particularly limited, and specific examples thereof include pyridine-2-carboxylic acid (picolinic acid), pyridine-3-carboxylic acid (nicotinic acid), pyridine-4-carboxylic acid (isonicotinic acid), 2-hydroxypyridine, 3-hydroxypyridine, 4-hydroxypyridine, 2-mercaptopyridine, 3-mercaptopyridine, 4-mercaptopyridine, 2-aminopyridine, 3-aminopyridine, 4-aminopyridine, pyridine-3,5-dicarboxylic acid, 2,3-dihydroxypyridine, pyridine-2-hydroxy-3-carboxylic acid, pyrimidine, 2-aminopyrimidine, 4-hydroxypyrimidine, 2-pyrimidinethiol, pyrimidine-4-carboxylic acid, 4,6-dihydroxypyrimidine, 4-amino-6-hydroxypyrimidine, 4,5-diaminopyrimidine, 2,4-diamino-1,3,5-triazine, 2,6-dihydroxyisonicotinic acid, 2-amino-4,6-dihydroxypyrimidine, 2,4-diamino-6-hydroxypyrimidine, 4,6-diamino-2-mercaptopyrimidine, cyanulic acid (trihydroxytriazine), nicotinamide, 6-methyl-nicotinamide, isonicotinamide, 2-amino-isonicotinamide, 6-amino-isonicotinamide, and adenine.

Among these, as the compound having a 6-membered heterocyclic structure, from the viewpoint of development residue inhibitory property and rust preventive property, at least one compound selected from the group consisting of pyridine-2-carboxylic acid, pyridine-3-carboxylic acid, 2-hydroxypyridine, 2-mercaptopyridine, 2-aminopyridine, 2,3-dihydroxypyridine, pyridine-2-hydroxy-3-carboxylic acid, pyrimidine, 2-aminopyrimidine, 4-hydroxypyrimidine, pyrimidine-4-carboxylic acid, 4,6-dihydroxypyrimidine, 2,6-dihydroxyisonicotinic acid, cyanulic acid, and adenine is preferable, at least one compound selected from the group consisting of pyridine-2-carboxylic acid, pyridine-3-carboxylic acid, 2-hydroxypyridine, 2,3-dihydroxypyridine, pyridine-2-hydroxy-3-carboxylic acid, 4-hydroxypyrimidine, pyrimidine-4-carboxylic acid, 4,6-dihydroxypyrimidine, and adenine is more preferable, at least one compound selected from the group consisting of pyridine-2-carboxylic acid, pyridine-3-carboxylic acid, 2-hydroxypyridine, 2,3-dihydroxypyridine, pyridine-2-hydroxy-3-carboxylic acid, pyrimidine, and adenine is particularly preferable, and pyrimidine or adenine is more particularly preferable in the present invention.

In addition, as the compound having a 6-membered heterocyclic structure, from the viewpoint of general-purpose properties, pyridine-3-carboxylic acid is preferable, and from the viewpoint of the balance between volatility and adsorptivity to the wire, at least one compound selected from the group consisting of pyridine-2-carboxylic acid, 2-hydroxypyridine, 2,3-dihydroxypyridine, pyridine-2-hydroxy-3-carboxylic acid, 4-hydroxypyrimidine, pyrimidine-4-carboxylic acid, and 4,6-dihydroxypyrimidine is preferable.

The compound having a 6-membered heterocyclic structure may be used alone or in combination of two or more thereof.

From the viewpoint of development residue inhibitory property and rust preventive property, a content of the compound having a 6-membered heterocyclic structure is preferably 0.01% by mass to 20% by mass, more preferably 0.05% by mass to 10% by mass, still more preferably 0.1% by mass to 2.0% by mass, and particularly preferably 0.2% by mass to 1.8% by mass with respect to the total solid content in the photosensitive resin composition.

The composition according to the embodiment of the present invention may include other components in addition to the components described above.

Examples of the other components which can be included in the composition according to the embodiment of the present invention include the same components as those included in the photosensitive resin layer described later.

[Metal Oxidation Inhibitor]

In addition, from the viewpoint of oxidation inhibitory property of metal in contact with the refractive index adjusting layer, the composition according to the embodiment of the present invention may include at least one metal oxidation inhibitor.

Preferred examples of the metal oxidation inhibitor include compounds other than the compound having a 6-membered heterocyclic structure, which have an aromatic ring including a nitrogen atom in the molecule.

Examples of the metal oxidation inhibitor include imidazole, triazole, benzimidazole, tetrazole, mercaptothiadiazole, and benzotriazole.

[Ethylenically Unsaturated Compound]

In a case where a cured product of the composition according to the embodiment of the present invention is used as a single-layer refractive index adjusting layer as a protective film in a touch panel, the composition according to the embodiment of the present invention preferably further has an ethylenically unsaturated compound.

The ethylenically unsaturated compound is preferably a radically polymerizable compound having an ethylenically unsaturated bond-containing group.

The radically polymerizable compound having an ethylenically unsaturated bond-containing group is a component which contributes to photosensitivity (that is, photocuring properties) of the refractive index adjusting layer and hardness of a cured film obtained by curing the refractive index adjusting layer.

In addition, the ethylenically unsaturated compound is a compound having one or more ethylenically unsaturated bond-containing groups.

The composition according to the embodiment of the present invention preferably includes a bi- or higher functional ethylenically unsaturated compound as the ethylenically unsaturated compound.

Here, the bi- or higher functional ethylenically unsaturated compound refers to a compound having two or more ethylenically unsaturated bond-containing groups in one molecule.

As the ethylenically unsaturated bond-containing group, a (meth)acryloyl group is more preferable.

As the ethylenically unsaturated compound, a (meth)acrylate compound is preferable.

From the viewpoint of curing properties after curing, the composition according to the embodiment of the present invention particularly preferably includes a bifunctional ethylenically unsaturated compound (preferably, a bifunctional (meth)acrylate compound) and a tri- or higher functional ethylenically unsaturated compound (preferably, a tri- or higher functional (meth)acrylate compound).

The bifunctional ethylenically unsaturated compound is not particularly limited and can be appropriately selected from a known compound.

Examples of the bifunctional ethylenically unsaturated compound include tricyclodecane dimethanol di(meth)acrylate, 1,9-nonanediol di(meth)acrylate, and 1,6-hexanediol di(meth)acrylate.

More specific examples of the bifunctional ethylenically unsaturated compound include tricyclodecanedimethanol diacrylate (product name: NK ESTER A-DCP, manufactured by Shin-Nakamura Chemical Co., Ltd.), tricyclodecanedimethanol dimethacrylate (product name: NK ESTER DCP, manufactured by Shin-Nakamura Chemical Co., Ltd.), 1,9-nonanediol diacrylate (product name: NK ESTER A-NOD-N, manufactured by Shin-Nakamura Chemical Co., Ltd.), and 1,6-hexanediol diacrylate (product name: NK ESTER A-HD-N, manufactured by Shin-Nakamura Chemical Co., Ltd.).

The tri- or higher functional ethylenically unsaturated compound is not particularly limited and can be appropriately selected from a known compound.

Examples of the tri- or higher functional ethylenically unsaturated compound include dipentaerythritol (tri/tetra/penta/hexa)(meth)acrylate, pentaerythritol (tri/tetra)(meth)acrylate, trimethylolpropane tri(meth)acrylate, ditrimethylolpropane tetra(meth)acrylate, isocyanuric acid (meth)acrylate, and a (meth)acrylate compound of a glycerin tri(meth)acrylate skeleton.

Here, the “(tri/tetra/penta/hexa)(meth)acrylate” has a concept including tri(meth)acrylate, tetra(meth)acrylate, penta(meth)acrylate, and hexa(meth)acrylate, and the “(tri/tetra)(meth)acrylate” has a concept including tri(meth)acrylate and tetra(meth)acrylate.

Examples of the tri- or higher functional ethylenically unsaturated compound include dipentaerythritol hexaacrylate (DPHA, manufactured by Toshin Yushi Co., Ltd.).

Examples of the ethylenically unsaturated compound also include a caprolactone-modified compound of a (meth)acrylate compound (KAYARAD (registered trademark) DPCA-20 manufactured by Nippon Kayaku Co., Ltd., A-9300-1CL manufactured by Shin-Nakamura Chemical Co., Ltd., or the like), an alkylene oxide-modified compound of a (meth)acrylate compound (KAYARAD RP-1040 manufactured by Nippon Kayaku Co., Ltd., ATM-35E, A-9300 manufactured by Shin-Nakamura Chemical Co., Ltd., EBECRYL (registered trademark) 135 manufactured by Daicel-Allnex Ltd., and the like), and ethoxylated glycerin triacrylate (A-GLY-9E manufactured by Shin-Nakamura Chemical Co., Ltd.).

As the ethylenically unsaturated compound, a urethane (meth)acrylate compound (preferably, a tri- or higher functional urethane (meth)acrylate compound) is also used.

Examples of the tri- or higher functional urethane (meth)acrylate compound include 8UX-015A (manufactured by Taisei Fine Chemical Co., Ltd.), NK ESTER UA-32P (manufactured by Shin-Nakamura Chemical Co., Ltd.), NK ESTER UA-1100H (manufactured by Shin-Nakamura Chemical Co., Ltd.), AH-600 (product name, manufactured by KYOEISHA CHEMICAL Co., LTD), UA-306H, UA-306T, UA-306I, UA-510H, and UX-5000 (all of which are manufactured by Nippon Kayaku Co., Ltd.).

In addition, from the viewpoint of improving developability, the ethylenically unsaturated compound preferably includes an ethylenically unsaturated compound having an acid group.

Examples of the acid group include a phosphoric acid group, a sulfonic acid group, and a carboxy group, and a carboxy group is preferable.

Examples of the ethylenically unsaturated compound including the acid group include a tri- or tetrafunctional ethylenically unsaturated compound including the acid group (component obtained by introducing a carboxy acid group to pentaerythritol tri- and tetra-acrylate (PETA) skeleton (acid value=80 to 120 mgKOH/g)), and a penta- to hexafunctional ethylenically unsaturated compound including the acid group (component obtained by introducing a carboxy group to dipentaerythritol penta- or hexaacrylate (DPHA) skeleton (acid value=25 to 70 mgKOH/g)). These tri- or higher functional ethylenically unsaturated compounds having an acid group may be used in combination with a bifunctional ethylenically unsaturated compound having an acid group, as necessary.

As the ethylenically unsaturated compound including the acid group, at least one kind selected from the group consisting of bi- or higher functional ethylenically unsaturated compound including carboxy group and a carboxylic acid anhydride thereof is preferable. As a result, developability and hardness of the cured film are enhanced.

The bi- or higher functional ethylenically unsaturated compound including a carboxy group is not particularly limited and can be suitably selected from well-known compounds.

For example, as the bi- or higher functional ethylenically unsaturated compound including a carboxy group, ARONIX (registered trademark) TO-2349 (manufactured by Toagosei Co., Ltd.), ARONIX M-520 (manufactured by Toagosei Co., Ltd.), or ARONIX M-510 (manufactured by Toagosei Co., Ltd.) can be preferably used.

The ethylenically unsaturated compound including the acid group is also preferably a polymerizable compound including an acid group disclosed in paragraphs 0025 to 0030 of JP2004-239942A. The content of this publication is incorporated in this specification.

<Compound M>

In the present invention, it is preferable that the ethylenically unsaturated compound is a compound M represented by Formula (M) (also simply referred to as a “compound M”).

Q²-R¹-Q¹ Formula (M)

In Formula (M), Q¹ and Q² each independently represent a (meth)acryloyloxy group, and R¹ represents a divalent linking group having a chain-like structure.

From the viewpoint of easiness of synthesis, it is preferable that Q¹ and Q² in Formula (M) have the same group.

In addition, from the viewpoint of reactivity, Q¹ and Q² in Formula (M) are preferably acryloyloxy groups.

From the viewpoint of bendability of the cured film to be obtained, R¹ in Formula (M) is preferably an alkylene group, an alkyleneoxyalkylene group (-L¹-O-L¹-), or a polyalkyleneoxyalkylene group (-(L¹-O)ₚ-L¹-), more preferably a hydrocarbon group having 2 to 20 carbon atoms or a polyalkyleneoxyalkylene group, still more preferably an alkylene group having 4 to 20 carbon atoms, and particularly preferably a linear alkylene group having 6 to 18 carbon atoms. It is sufficient that the above-described hydrocarbon group has a chain-like structure at least in part, and a portion other than the chain-like structure is not particularly limited. For example, the portion may be a branched chain, a cyclic or a linear alkylene group, an arylene group, an ether bond, or a combination thereof, and from the viewpoint of bendability of the cured film to be obtained, an alkylene group or a group in which two or more alkylene groups and one or more arylene groups are combined is preferable, an alkylene group is more preferable, and a linear alkylene group is particularly preferable.

The above-described L¹'s each independently represent an alkylene group, and an ethylene group, a propylene group, or a butylene group is preferable and an ethylene group or a 1,2-propylene group is more preferable. p represents an integer of 2 or more, and is preferably an integer of 2 to 10.

In addition, from the viewpoint of water vapor permeability and bendability of the cured film to be obtained, the number of atoms in the shortest linking chain which links Q¹ and Q² in the compound M is preferably 3 to 50, more preferably 4 to 40, still more preferably 6 to 20, and particularly preferably 8 to 12.

In the present disclosure, the “number of atoms in the shortest linking chain which links Q¹ and Q²” is the shortest number of atoms linking from an atom in R¹ linked to Q¹ to an atom in R¹ linked to Q².

Specific examples of the compound M include 1,3-butanediol di(meth)acrylate, tetramethylene glycol di(meth)acrylate, neopentyl glycol di(meth)acrylate, 1,6-hexanediol di(meth)acrylate, 1,7-heptanediol di(meth)acrylate, 1,8-octanediol di(meth)acrylate, 1,9-nonanediol di(meth)acrylate, 1,10-decanediol di(meth)acrylate, 1,4-cyclohexanediol di(meth)acrylate, tricyclodecane dimethanol di(meth)acrylate, hydrogenated bisphenol A di(meth)acrylate, hydrogenated bisphenol F di(meth)acrylate, polyethylene glycol di(meth)acrylate, polypropylene glycol di(meth)acrylate, poly (ethylene glycol/propylene glycol) di(meth)acrylate, and polybutylene glycol di(meth)acrylate. The above-described ester monomers can also be used as a mixture.

Among the above-described compounds, from the viewpoint of bendability of the cured film to be obtained, at least one compound selected from the group consisting of 1,6-hexanediol di(meth)acrylate, 1,9-nonanediol di(meth)acrylate, 1,10-decanediol di(meth)acrylate, and neopentyl glycol di(meth)acrylate is preferable, at least one compound selected from the group consisting of 1,6-hexanediol di(meth)acrylate, 1,9-nonanediol di(meth)acrylate, and 1,10-decanediol di(meth)acrylate is more preferable, and at least one compound selected from the group consisting of 1,9-nonanediol di(meth)acrylate and 1,10-decanediol di(meth)acrylate is particularly preferable.

The compound M may be used alone or in combination of two or more thereof.

A weight-average molecular weight (Mw) of the ethylenically unsaturated compound is preferably 200 to 3,000, more preferably 250 to 2,600, still more preferably 280 to 2,200, and particularly preferably 300 to 2, 200.

In addition, a proportion of a content of an ethylenically unsaturated compound having a weight-average molecular weight of 300 or less, among all of the ethylenically unsaturated compound used in the composition according to the embodiment of the present invention, is preferably 30% by mass or less, more preferably 25% by mass or less, and still more preferably 20% by mass or less, with respect to all of the ethylenically unsaturated compounds contained in the composition according to the embodiment of the present invention.

The ethylenically unsaturated compound may be used alone or in combination of two or more thereof.

In the case where a single-layer refractive index adjusting layer formed of a cured product of the composition according to the embodiment of the present invention can be used as a protective film in a touch panel, from the viewpoint of ensuring transferability (pressure-sensitive adhesion to a base material) and curing properties in a single layer, the content of the ethylenically unsaturated compound in the composition according to the embodiment of the present invention is preferably 1% by mass to 60% by mass, more preferably 5% by mass to 50% by mass, still more preferably 10% by mass to 40% by mass, and particularly preferably 10% by mass to 20% by mass with respect to the total mass of the composition according to the embodiment of the present invention.

In the case where a cured product of the composition according to the embodiment of the present invention is used as a refractive index adjusting layer and a cured product of a photosensitive resin layer is used as a protective film in a touch panel, since the photosensitive resin layer is responsible for transferability and curing properties, the amount of the ethylenically unsaturated compound in the refractive index adjusting layer can be reduced.

In this case, the content of the ethylenically unsaturated compound is preferably 0.1% by mass to 60% by mass, more preferably 0.5% by mass to 10% by mass, and particularly preferably 1.0% by mass to 5% by mass with respect to the total mass of the composition according to the embodiment of the present invention.

In addition, in a case where the composition according to the embodiment of the present invention includes a bifunctional ethylenically unsaturated compound and a tri- or higher functional ethylenically unsaturated compound, the content of the bifunctional ethylenically unsaturated compound is preferably 10% by mass to 90% by mass, more preferably 20% by mass to 85% by mass, and still more preferably 30% by mass to 80% by mass with respect to all of the ethylenically unsaturated compounds included in the composition according to the embodiment of the present invention.

In this case, the content of the tri- or higher functional ethylenically unsaturated compound is preferably 10% by mass to 90% by mass, more preferably 15% by mass to 80% by mass, and still more preferably 20% by mass to 70% by mass with respect to all of the ethylenically unsaturated compounds included in the composition according to the embodiment of the present invention.

In this case, the content of the bi- or higher functional ethylenically unsaturated compound is preferably 40% by mass or more and less than 100% by mass, more preferably 40% by mass to 90% by mass, still more preferably 50% by mass to 80% by mass, and particularly preferably 50% by mass to 70% by mass with respect to a total content of the bifunctional ethylenically unsaturated compound and the tri- or higher functional ethylenically unsaturated compound.

In addition, in a case where the composition according to the embodiment of the present invention contains the bi- or higher functional ethylenically unsaturated compound, the composition according to the embodiment of the present invention may further contain a monofunctional ethylenically unsaturated compound.

Further, in a case where the composition according to the embodiment of the present invention contains the bi- or higher functional ethylenically unsaturated compound, the bi- or higher functional ethylenically unsaturated compound is preferably the main component of the ethylenically unsaturated compound contained in the composition according to the embodiment of the present invention.

Specifically, in a case where the composition according to the embodiment of the present invention contains the bi- or higher functional ethylenically unsaturated compound, the content of the bi- or higher functional ethylenically unsaturated compound is preferably 60% by mass to 100% by mass, more preferably 80% by mass to 100% by mass, and particularly preferably 90% by mass to 100% by mass with respect to a total content of the ethylenically unsaturated compounds contained in the composition according to the embodiment of the present invention.

In addition, the composition according to the embodiment of the present invention preferably contains an ethylenically unsaturated compound having an acid group (preferably, a bi- or higher functional ethylenically unsaturated compound containing a carboxy group or a carboxylic acid anhydride thereof). The content of the ethylenically unsaturated compound having an acid group is preferably 1% by mass to 50% by mass, more preferably 1% by mass to 20% by mass, and still more preferably 1% by mass to 10% by mass with respect to the composition according to the embodiment of the present invention.

The ethylenically unsaturated compound may be used alone or in combination of two or more thereof.

[Photopolymerization Initiator]

The composition according to the embodiment of the present invention may include a photopolymerization initiator.

In particular, in the case where a single-layer refractive index adjusting layer formed of a cured product of the composition according to the embodiment of the present invention can be used as a protective film in a touch panel, the composition according to the embodiment of the present invention preferably includes a photopolymerization initiator.

The photopolymerization initiator is not particularly limited and a known photopolymerization initiator can be used.

Examples of the photopolymerization initiator include a photopolymerization initiator having an oxime ester structure (hereinafter, also referred to as an “oxime-based photopolymerization initiator”), a photopolymerization initiator having an α-aminoalkylphenone structure (hereinafter, also referred to as an “α-aminoalkylphenone-based photopolymerization initiator”), a photopolymerization initiator having an α-hydroxyalkylphenone structure (hereinafter also referred to as an “α-hydroxyalkylphenone-based photopolymerization initiator”), a photopolymerization initiator having an acylphosphine oxide structure, (hereinafter, also referred to as an “acylphosphine oxide-based photopolymerization initiator”), and a photopolymerization initiator having an N-phenylglycine structure (hereinafter, also referred to as an “N-phenylglycine-based photopolymerization initiator”).

The photopolymerization initiator preferably includes at least one kind selected from the group consisting of the oxime-based photopolymerization initiator, the α-aminoalkylphenone-based photopolymerization initiator, the α-hydroxyalkylphenone-based photopolymerization initiator, and the N-phenylglycine-based photopolymerization initiator, and more preferably includes at least one kind selected from the group consisting of the oxime-based photopolymerization initiator, the α-aminoalkylphenone-based photopolymerization initiator, and the N-phenylglycine-based photopolymerization initiator.

In addition, as the photopolymerization initiator, for example, polymerization initiators disclosed in paragraphs 0031 to 0042 of JP2011-95716A and paragraphs 0064 to 0081 of JP2015-014783A may be used.

Examples of a commercially available product of the photopolymerization initiator include 1-[4-(phenylthio)phenyl]-1,2-octanedione-2-(O-benzoyloxime) [product name: IRGACURE (registered trademark) OXE-01, manufactured by BASF SE], 1-[9-ethyl-6-(2-methylbenzoyl)-9H-carbazol-3-yl]ethanone-1-(O-acetyloxime) [product name: IRGACURE (registered trademark) OXE-02, manufactured by BASF SE], IRGACURE (registered trademark) OXE03 (manufactured by BASF SE), IRGACURE (registered trademark) OXE04 (manufactured by BASF SE), 2-(dimethylamino)-2-[(4-methylphenyl)methyl]-1-[4-(4-morpholinyl)phenyl]-1-butanone [product name: IRGACURE (registered trademark) 379EG, manufactured by BASF SE], 2-methyl-1-(4-methylthiophenyl)-2-morpholinopropan-1-one [product name: IRGACURE (registered trademark) 907, manufactured by BASF SE], 2-hydroxy-1-{4-[4-(2-hydroxy-2-methylpropionyl)benzyl]phenyl}-2-methylpropan-1-one [product name: IRGACURE (registered trademark) 127, manufactured by BASF SE], 2-benzyl-2-dimethylamino-1-(4-morpholinophenyl)butanone-1 [product name: IRGACURE (registered trademark) 369, manufactured by BASF SE], 2-hydroxy-2-methyl-1-phenylpropan-1-one [product name: IRGACURE (registered trademark) 1173, manufactured by BASF SE], 1-hydroxy cyclohexyl phenyl ketone [product name: IRGACURE (registered trademark) 184, manufactured by BASF SE], 2,2-dimethoxy-1,2-diphenylethan-1-one (product name: IRGACURE (registered trademark) 651, manufactured by BASF SE], an oxime ester-based product [product name: Lunar (registered trademark) 6, manufactured by DKSH Management Ltd.], 1-[4-(phenylthio)phenyl]-3-cyclopentylpropan-1,2-dione-2-(O-benzoyloxime) (product name: TR-PBG-305, manufactured by TRONLY), 1,2-propanedione, 3-cyclohexyl-1-[9-ethyl-6-(2-furanylcarbonyl)-9H-carbazole-3-yl]-, 2-(O-acetyloxime) (product name: TR-PBG-326, manufactured by TRONLY), 3-cyclohexyl-1-(6-(2-(benzoyloxyimino)hexanoyl)-9-ethyl-9H-carbazole-3-yl)-propan-1,2-dione-2-(O-benzoyloxime) (product name: TR-PBG-391, manufactured by TRONLY), and (1-(biphenyl-4-yl)-2-methyl-2-morpholinopropan-1-one (trade name: APi-307, manufactured by Shenzhen UV ChemTech Co., Ltd.).

A content of the photopolymerization initiator is not particularly limited, but is preferably 0.1% by mass or more, more preferably 0.5% by mass or more, and still more preferably 1.0% by mass or more with respect to the total solid content of the composition according to the embodiment of the present invention.

In addition, the content of the photopolymerization initiator is preferably 10% by mass or less and more preferably 5% by mass or less with respect to the total solid content of the composition according to the embodiment of the present invention.

The photopolymerization initiator may be used alone, or two or more thereof may be used in combination.

[Surfactant]

The composition according to the embodiment of the present invention may include a surfactant.

The surfactant is not particularly limited, and a known surfactant can be used.

Examples of the surfactant include surfactants described in paragraph 0017 of JP4502784B and paragraphs 0060 to 0071 of JP2009-237362A.

As the surfactant, a fluorine-based surfactant or a silicon-based surfactant is preferable.

Examples of a commercially available product of the fluorine-based surfactant include: MEGAFACE F-171, F-172, F-173, F-176, F-177, F-141, F-142, F-143, F-144, F-437, F-475, F-477, F-479, F-482, F-551-A, F-552, F-554, F-555-A, F-556, F-557, F-558, F-559, F-560, F-561, F-565, F-563, F-568, F-575, F-780, EXP, MFS-330, R-41, R-41-LM, R-01, R-40, R-40-LM, RS-43, TF-1956, RS-90, R-94, RS-72-K, and DS-21 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); POLYFOX PF636, PF656, PF6320, PF6520, and PF7002 (all of which are manufactured by OMNOVA Solutions Inc.); and FTERGENT 710FM, 610FM, 601AD, 601ADH2, 602A, 215M, 245F, 251, 212M, 250, 209F, 222F, 208G, 710LA, 710FS, 730LM, 650AC, and 681 (all of which are manufactured by NEOS COMPANY LIMITED).

In addition, as the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of such a fluorine-based surfactant include MEGAFACE DS series manufactured by DIC Corporation (The Chemical Daily (Feb. 22, 2016) and Nikkei Business Daily (Feb. 23, 2016)), for example, MEGAFACE DS-21.

In addition, it is also preferable that a polymer of a fluorine atom-containing vinyl ether compound having a fluorinated alkyl group or a fluorinated alkylene ether group, and a hydrophilic vinyl ether compound is used as the fluorine-based surfactant.

A block polymer can also be used as the fluorine-based surfactant. As the fluorine-based surfactant, a fluorine-containing polymer compound can be preferably used, the fluorine-containing polymer compound including: a repeating unit derived from a (meth)acrylate compound having a fluorine atom; and a repeating unit derived from a (meth)acrylate compound having 2 or more (preferably 5 or more) alkyleneoxy groups (preferably an ethyleneoxy group and a propyleneoxy group).

As the fluorine-based surfactant, a fluorine-containing polymer having an ethylenically unsaturated bond-containing group in the side chain can be used. Examples thereof include MEGAFACE RS-101, RS-102, RS-718K, and RS-72-K (all of which are manufactured by DIC Corporation.

Examples of the silicon-based surfactant include a linear polymer consisting of a siloxane bond and a modified siloxane polymer with an organic group introduced in the side chain or the terminal.

Examples of a commercially available product of the silicon-based surfactant include DOWSIL 8032 ADDITIVE, TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.), X-22-4952, X-22-4272, X-22-6266, KF-351A, K354L, KF-355A, KF-945, KF-640, KF-642, KF-643, X-22-6191, X-22-4515, KF-6004, KP-341, KF-6001, and KF-6002 (all of which are manufactured by Shin-Etsu Chemical Co., Ltd.), F-4440, TSF-4300, TSF-4445, TSF-4460, and TSF-4452 (all of which are manufactured by Momentive Performance Materials Co., Ltd.), and BYK307, BYK323, and BYK330 (all of which are manufactured by BYK Chemie).

Examples of a nonionic surfactant include glycerol, trimethylolpropane, trimethylolethane, and ethoxylate and propoxylate thereof (for example, glycerol propoxylate, glycerol ethoxylate, and the like), polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, and sorbitan fatty acid ester.

Examples of a commercially available product of the nonionic surfactant include PLURONIC L10, L31, L61, L62, 10R5, 17R2, and 25R2 (all of which are manufactured by BASF SE), TETRONIC 304, 701, 704, 901, 904, and 150R1 (all of which are manufactured by BASF SE), SOLSPERSE 20000 (manufactured by Lubrizol Corporation), NCW-101, NCW-1001, and NCW-1002 (all of which are manufactured by FUJIFILM Wako Pure Chemical Corporation), PIONIN D-6112, D-6112-W, and D-6315 (all of which are manufactured by Takemoto Oil&Fat Co., Ltd.), and OLFINE E1010 and SURFYNOL 104, 400, and 440 (all of which are manufactured by Nissin Chemical Co., Ltd.).

The composition according to the embodiment of the present invention may include only one kind or two or more kinds of the surfactants.

In a case of including a surfactant, a content of the surfactant is preferably 0.01% by mass to 3.0% by mass, more preferably 0.05% by mass to 1.0% by mass, and still more preferably 0.10% by mass to 0.80% by mass with respect to the total solid content of the composition according to the embodiment of the present invention.

[Solvent]

The composition according to the embodiment of the present invention preferably includes a solvent.

In a case where the composition according to the embodiment of the present invention includes a solvent, a formation of the refractive index adjusting layer by coating tends to be easier.

As the solvent, a generally used solvent can be used without particular limitation.

As the solvent, an aqueous solvent or an organic solvent is preferable.

Depending on the type of a base layer in a case where a transfer film is formed using the composition according to the embodiment of the present invention, the type of the solvent can be appropriately selected.

For example, in a case where a base layer of the refractive index adjusting layer is a temporary support in a case where a transfer film is formed using the composition according to the embodiment of the present invention, either an aqueous solvent or an organic solvent can be selected. Alternatively, in a case where a base layer of the refractive index adjusting layer is an interlayer, a solvent which does not dissolve the interlayer can be appropriately selected.

On the other hand, in a case where a transfer film according to the embodiment of the present invention has a photosensitive resin layer between the refractive index adjusting layer and the temporary support, for example, in a case where the photosensitive resin layer is formed of a photosensitive resin composition having an aspect of including an organic solvent, it is preferable to select an aqueous solvent for the composition according to the embodiment of the present invention.

As the aqueous solvent, an aqueous solvent described in paragraphs 0161 and 0162 of JP2018-024226A can be used, and the contents of this specification are incorporated in the present disclosure. For example, as the aqueous solvent, water or a mixed solvent of a lower alcohol having 1 to 3 carbon atoms and water is preferable. It is preferable to include water and an alcohol having 1 to 3 carbon atoms, and it is more preferable to include water or a mixed solvent having a mass ratio of alcohol having 1 to 3 carbon atoms/water of 20/80 to 80/20. As the mixed solvent, a mixed solvent of water and methanol or a mixed solvent of water and ethanol is preferable, and from the viewpoint of drying and coating properties, a mixed solvent of water and methanol is preferable. In particular, in a case where a mixed solvent of water and methanol (MeOH) is used in a case of forming the refractive index adjusting layer, a mass ratio (% by mass ratio) of MeOH/water is preferably 20/80 to 80/20, more preferably 30/70 to 75/25, and still more preferably 40/60 to 70/30. By controlling within the above-described range, coating and rapid drying can be realized without the photosensitive resin layer and the refractive index adjusting layer being layered and mixed with each other at the interface.

Examples of the organic solvent include methyl ethyl ketone, propylene glycol monomethyl ether, propylene glycol monomethyl ether acetate (also known as 1-methoxy-2-propyl acetate), diethylene glycol ethyl methyl ether, cyclohexanone, methyl isobutyl ketone, ethyl lactate, methyl lactate, caprolactam, n-propanol, and 2-propanol.

As the solvent, a mixed solvent of methyl ethyl ketone and propylene glycol monomethyl ether acetate or a mixed solvent of diethylene glycol ethyl methyl ether and propylene glycol monomethyl ether acetate is preferably used.

As the solvent, a solvent described in paragraphs 0054 and 0055 of US2005/282073A can also be used, and the contents of this specification are incorporated in the present disclosure.

In addition, as the solvent, an organic solvent (high-boiling-point solvent) having a boiling point of 180° C. to 250° C. can also be used, as necessary.

In a case where the composition according to the embodiment of the present invention includes a solvent, the composition according to the embodiment of the present invention may include only one kind of the solvent, or may include two or more kinds thereof.

In a case of including the solvent, the solid content of the composition according to the embodiment of the present invention is preferably 0.5% by mass to 80% by mass, more preferably 1.0% by mass to 40% by mass, and particularly preferably 1.5% by mass to 30% by mass with respect to the total mass of the composition according to the embodiment of the present invention.

In a case where the composition according to the embodiment of the present invention includes the solvent, for example, from the viewpoint of coating properties, a viscosity of the composition according to the embodiment of the present invention at 25° C. is preferably 1 mPa·s to 50 mPa·s, more preferably 2 mPa·s to 40 mPa·s, and still more preferably 3 mPa·s to 30 mPa·s.

The viscosity is measured using a viscometer. As the viscometer, for example, a viscometer (product name: VISCOMETER TV-22) manufactured by Toki Sangyo Co., Ltd. can be suitably used. However, the viscometer is not limited thereto.

In a case where the composition according to the embodiment of the present invention includes the solvent, for example, from the viewpoint of coating properties, a surface tension of the composition according to the embodiment of the present invention at 25° C. is preferably 5 mN/m to 100 mN/m, more preferably 10 mN/m to 80 mN/m, and still more preferably 15 mN/m to 40 mN/m.

The surface tension is measured using a tensiometer. As the tensiometer, for example, a tensiometer (product name: Automatic Surface Tensiometer CBVP-Z) manufactured by Kyowa Interface Science Co., Ltd. can be suitably used. However, the tensiometer is not limited thereto.

[Other Components]

With regard to other components of the composition according to the embodiment of the present invention, components of a curable second resin layer described in paragraphs 0019 to 0040 and 0144 to 0150 of JP2014-108541A, and components of a transparent layer described in paragraphs 0024 to 0035 and 0110 to 0112 of JP2014-10814A, and components of a composition including ammonium salt described in paragraphs 0034 to 0056 of WO2016/009980A can be referred to.

[Impurities]

In the composition according to the embodiment of the present invention, from the viewpoint of improving reliability and patterning properties, it is preferable that the composition according to the embodiment of the present invention and the photosensitive resin layer described later have a low content of impurities.

Specific examples of the impurities include sodium, potassium, magnesium, calcium, iron, manganese, copper, aluminum, titanium, chromium, cobalt, nickel, zinc, tin, ions of these, and halide ions (chloride ion, bromide ion, iodide ion, and the like). Among these, since the sodium ion, potassium ion, and chloride ion are easily mixed as impurities, the following content is particularly preferable.

The content of impurities in each layer is preferably 1,000 ppm or less, more preferably 200 ppm or less, particularly preferably 40 ppm or less, more particularly preferably 10 ppm or less, and still more particularly preferably 5 ppm or less on a mass basis. Although the lower limit is not particularly defined, from the viewpoint of the limit that can be reduced realistically and the limit of measurement, the lower limit may be 10 ppb or more or 100 ppb or more on a mass basis.

Examples of a method for reducing the impurities to the above-described range include selecting a raw material of each layer including no impurities, preventing the impurities from being mixed in a case of forming the layer, and washing and removing the impurities. By such a method, the amount of impurities can be kept within the above-described range.

The impurities can be quantified by a known method such as inductively coupled plasma (ICP) emission spectroscopy, atomic absorption spectroscopy, and ion chromatography.

In addition, it is preferable that the content of compounds such as benzene, formaldehyde, trichlorethylene, 1,3-butadiene, carbon tetrachloride, chloroform, N,N-dimethylformamide, N,N-dimethylacetamide, and hexane is low in each layer. The content of these compounds in each layer is preferably 1,000 ppm or less, more preferably 200 ppm or less, particularly preferably 40 ppm or less, more particularly preferably 10 ppm or less, and still more particularly preferably 5 ppm or less on a mass basis. Although the lower limit is not particularly defined, from the viewpoint of the limit that can be reduced realistically and the limit of measurement, the lower limit may be 10 ppb or more or 100 ppb or more on a mass basis.

The content of compounds as impurities can be suppressed in the same manner as in the above-described metal as impurities. In addition, the compounds can be quantified by a known measurement method.

[Producing Method of Composition]

A producing method of a composition according to an embodiment of the present invention includes a step of preparing a composition using metal oxide particles, a binder polymer having an acid group, and an amine compound, in which the amine compound has, as a substituent on a nitrogen atom in the amine compound, a substituent which includes a linking group having a linking chain length of 3 or more, and a weight-average molecular weight of the amine compound is 100 or more.

The step of preparing a composition using metal oxide particles, a binder polymer having an acid group, and an amine compound is not particularly limited, and the composition can be prepared by a known method.

Other preferred aspects of the method for a composition according to the embodiment of the present invention are the same as the preferred aspects of the composition according to the embodiment of the present invention.

[Cured Film]

A cured film according to an embodiment of the present invention is a cured film of the composition according to the embodiment of the present invention.

Preferred aspects of the cured film according to the embodiment of the present invention is substantially the same as the preferred aspects of the composition according to the embodiment of the present invention, except that, in a case where the composition contains an ethylenically unsaturated compound, the ethylenically unsaturated compound is cured, and in a case where the composition contains a polymerization initiator, the polymerization initiator is decomposed.

[Transfer Film]

A transfer film according to an embodiment of the present invention has a temporary support and a refractive index adjusting layer including the composition according to the embodiment of the present invention.

Hereinafter, each layer of the transfer film according to the embodiment of the present invention will be described in detail.

[Temporary Support]

The transfer film according to the embodiment of the present invention has a temporary support.

The temporary support is preferably a film and more preferably a resin film. As the temporary support, a film which has flexibility and does not generate significant deformation, contraction, or stretching under pressure or under pressure and heating can be used.

Examples of such a film include a polyethylene terephthalate film (for example, a biaxial stretching polyethylene terephthalate film), a cellulose triacetate film, a polystyrene film, a polyimide film, and a polycarbonate film.

Among these, as the temporary support, a biaxial stretching polyethylene terephthalate film is particularly preferable.

In addition, it is preferable that the film used as the temporary support does not have deformation such as wrinkles or scratches.

From the viewpoint that pattern exposure through the temporary support can be performed, the temporary support preferably has high transparency, and the transmittance at 365 nm is preferably 60% or more and more preferably 70% or more.

From the viewpoint of pattern formation during pattern exposure through the temporary support and transparency of the temporary support, it is preferable that the haze of the temporary support is small. Specifically, a haze value of the temporary support is preferably 2% or less, more preferably 0.5% or less, and particularly preferably 0.1% or less.

From the viewpoint of pattern formation during pattern exposure through the temporary support and transparency of the temporary support, it is preferable that the number of fine particles, foreign substances, and defects included in the temporary support is small. The number of fine particles, foreign substances, and defects having a diameter of 1 μm or more is preferably 50 pieces/10 mm² or less, more preferably 10 pieces/10 mm² or less, still more preferably 3 pieces/10 mm² or less, and particularly preferably 0 pieces/10 mm².

In the temporary support included in the transfer film according to the embodiment of the present invention, an arithmetic average roughness Ra of a surface on the refractive index adjusting layer side is 50 nm or less, preferably 1 to 20 nm and more preferably 1 to 12 nm.

Here, the arithmetic average roughness Ra is an arithmetic average roughness according to JIS B0601: 2001 measured using an optical surface texture measuring instrument.

In the present invention, from the viewpoint of adjusting the arithmetic average roughness Ra of the surface of the temporary support on the refractive index adjusting layer side to the above-described range, the temporary support may contain particles, and as a layer structure included in the temporary support, a particle-containing layer constituting the surface on the refractive index adjusting layer side may be provided.

From the viewpoint of further improving handleability, the temporary support preferably has a layer in which 1 particle/mm² having a diameter of 0.5 μm to 5 μm is present on a surface opposite to the side where the refractive index adjusting layer is formed, and it is more preferable that 1 to 50 particles/mm² are present.

The particles contained in the temporary support (particularly, the particle-containing layer) may be organic particles or inorganic particles.

Specific examples of the organic particles include a polyimide-based resin, an olefin or modified olefin-based resin, a crosslinked polystyrene-based resin, and a silicone resin.

Specific examples of the inorganic particles include silicon oxide, calcium carbonate, aggregated alumina, aluminum silicate, mica, clay, talc, and barium sulfate.

In addition, by adjusting the number and particle size of the particles contained in the temporary support, the arithmetic average roughness Ra of the surface of the temporary support on the refractive index adjusting layer side can be adjusted within the above-described range.

A thickness of the temporary support is not particularly limited, but is preferably 5 μm to 200 μm. In addition, from the viewpoint of ease of handling and general-purpose properties, the thickness of the temporary support is more preferably 10 μm to 150 μm and still more preferably 10 to 50 μm.

Preferred aspects of the temporary support are described in, for example, paragraphs 0017 and 0018 of JP2014-85643A, paragraphs 0019 to 0026 of JP2016-27363A, paragraphs 0041 to 0057 of WO2012/081680A, and paragraphs 0029 to 0040 of WO2018/179370A, and the contents of these publications are incorporated in the present specification.

The temporary support is available as, for example, LUMIRROR (registered trademark) 16FB40 manufactured by Toray Industries, Inc., and LUMIRROR (registered trademark) 16QS62 (16KS40) manufactured by Toray Industries, Inc.

In addition, particularly preferred examples of the temporary support include a biaxial stretching polyethylene terephthalate film having a thickness of 16 μm, a biaxial stretching polyethylene terephthalate film having a thickness of 12 μm, and a biaxial stretching polyethylene terephthalate film having a thickness of 10 μm.

[Refractive Index Adjusting Layer]

The transfer film according to the embodiment of the present invention has a refractive index adjusting layer including the composition according to the embodiment of the present invention.

A refractive index of the refractive index adjusting layer is preferably 1.50 or more, more preferably 1.55 or more, still more preferably 1.60 or more, and particularly preferably 1.70 or more.

The upper limit of the refractive index of the refractive index adjusting layer is not particularly limited, but is preferably 2.10 or less, more preferably 1.85 or less, still more preferably 1.78 or less, and particularly preferably 1.74 or less.

The refractive index adjusting layer may have photocuring properties (that is, photosensitivity), may have thermosetting properties, or may have both photocuring properties and thermosetting properties, but from the viewpoint of forming a cured film having excellent hardness, it is preferable to have photocuring properties.

The refractive index adjusting layer preferably has alkali solubility (for example, solubility with respect to weak alkali aqueous solution).

A thickness of the refractive index adjusting layer is not particularly limited.

In the case where a single-layer refractive index adjusting layer formed of a cured product of the composition according to the embodiment of the present invention can be used as a protective film in a touch panel, from the viewpoint of exerting sufficient surface protection ability, the thickness of the refractive index adjusting layer is preferably 0.5 to 20 μm, more preferably 0.8 to 10 μm, and particularly preferably 1 to 5 μm.

In the case where a cured product of the composition according to the embodiment of the present invention is used as a refractive index adjusting layer (that is, the case where a separately prepared cured product of a photosensitive resin layer can be used as a protective film in a touch panel), the thickness of the refractive index adjusting layer is preferably 50 nm to 500 nm, more preferably 55 nm to 110 nm, and still more preferably 60 nm to 100 nm.

The thickness of the refractive index adjusting layer is obtained as an average value of 5 random points measured by cross-sectional observation with a scanning electron microscope (SEM).

In the present invention, a method for controlling the refractive index of the refractive index adjusting layer is not particularly limited except that metal oxide particles and a binder polymer are used, and examples thereof include a method using a binder polymer having an arbitrary refractive index and metal oxide particles, a method using a binder polymer having a predetermined high refractive index and metal oxide particles, a method using a composite of metal oxide particles and a binder polymer, and a method further using metal particles and a metal salt with these methods.

A forming method of the refractive index adjusting layer is not particularly limited.

As an example of the forming method of the refractive index adjusting layer, a method of forming a refractive index adjusting layer by applying and, as necessary, drying a composition (aqueous resin composition) for forming the refractive index adjusting layer including an aqueous solvent, on a photosensitive resin layer described later, formed on the temporary support is used.

As a coating method, a known method can be used.

Examples of the coating method include a printing method, a spray method, a roll coating method, a bar coating method, a curtain coating method, a spin coating method, and a die coating method (that is, a slit coating method).

Among these, a die coating method is preferable as the coating method.

As a drying method, known methods such as natural drying, heating drying, and drying under reduced pressure can be used, and these methods can be applied alone or in combination of plural thereof.

In the present disclosure, the “drying” means removing at least a part of the solvent included in the composition.

[Color of Refractive Index Adjusting Layer]

The refractive index adjusting layer and a cured film thereof are preferably achromatic. Specifically, in CIE1976 (L*, a*, b*) color space of the total reflection (incidence angle: 8°, light source: D-65 (visual field: 2°)), the L* value is preferably 10 to 90, the a* value is preferably −1.0 to 1.0, and the b* value is preferably −1.0 to 1.0.

[Photosensitive Resin Layer]

The transfer film according to the embodiment of the present invention preferably has a photosensitive resin layer between the refractive index adjusting layer and the temporary support. It is preferable that the photosensitive resin layer has a lower refractive index than the refractive index adjusting layer.

The photosensitive resin layer included in the transfer film according to the embodiment of the present invention preferably contains a binder polymer, an ethylenically unsaturated compound, and a photopolymerization initiator, and is more preferably formed of a photosensitive resin composition containing a binder polymer, a polymerizable monomer, and a photopolymerization initiator.

<Binder Polymer>

As the binder polymer included in the photosensitive resin layer, the same binder polymer as the binder polymer having an acid group, which is included in the composition according to the embodiment of the present invention, can be used, and the preferred type is also the same. From the viewpoint of hardness of the cured film and handleability of the transfer film, for example, a content of the binder polymer in the photosensitive resin layer is preferably 10% by mass to 90% by mass, more preferably 20% by mass to 80% by mass, and still more preferably 30% by mass to 70% by mass with respect to a total mass of the photosensitive resin layer (or the total solid content of the photosensitive resin composition).

<Ethylenically Unsaturated Compound>

As the ethylenically unsaturated compound included in the photosensitive resin layer, the same ethylenically unsaturated compound as the radically polymerizable compound having an ethylenically unsaturated bond-containing group, which is included in the composition according to the embodiment of the present invention, can be used, and the preferred type is also the same.

However, from the viewpoint of water vapor permeability and bendability of the cured product of the photosensitive resin layer, and pressure-sensitive adhesiveness of the uncured film to be obtained, the ethylenically unsaturated compound included in the photosensitive resin layer or the photosensitive resin composition forming the photosensitive resin layer preferably includes a bifunctional ethylenically unsaturated compound having an aliphatic hydrocarbon ring structure, more preferably includes a bifunctional ethylenically unsaturated compound having a ring structure in which two or more aliphatic hydrocarbon rings are fused, and particularly preferably includes tricyclodecane dimethanol di(meth)acrylate.

From the viewpoint of water vapor permeability and bendability of the cured product of the photosensitive resin layer, and pressure-sensitive adhesiveness of the uncured film to be obtained, the above-described aliphatic hydrocarbon ring structure is preferably a cyclopentane ring structure, a cyclohexane ring structure, a tricyclodecane ring structure, a norbornane ring structure, or an isophorone ring structure, more preferably a cyclohexane ring structure or a tricyclodecane ring structure, and particularly preferably a tricyclodecane ring structure.

The photosensitive resin composition may contain one bifunctional ethylenically unsaturated compound having an aliphatic hydrocarbon ring structure alone, or two or more kinds thereof.

From the viewpoint of water vapor permeability and bendability of the cured film to be obtained, and pressure-sensitive adhesiveness of the cured product of the photosensitive resin layer, a content of the bifunctional ethylenically unsaturated compound having an aliphatic hydrocarbon ring structure is preferably 1% by mass to 50% by mass, more preferably 5% by mass to 40% by mass, still more preferably 10% by mass to 30% by mass, and particularly preferably 15% by mass to 25% by mass with respect to the total solid content of the photosensitive resin composition.

The content of the ethylenically unsaturated compound in the photosensitive resin layer is preferably 1% by mass to 70% by mass, more preferably 5% by mass to 70% by mass, still more preferably 10% by mass to 70% by mass, particularly preferably 20% by mass to 60% by mass, and most preferably 20% by mass to 50% by mass, with respect to the total mass of the photosensitive resin layer.

In the photosensitive resin layer or the photosensitive resin composition forming the photosensitive resin layer, the ethylenically unsaturated compound may be used alone or in combination of two or more thereof, and it is preferable to use in combination of two or more thereof.

In the photosensitive resin layer or the photosensitive resin composition, as the ethylenically unsaturated compound, from the viewpoint of substrate adhesiveness, development residue inhibitory property, and rust preventive property, it is preferable to use the compound (compound M) represented by Formula (M) described above, the ethylenically unsaturated compound having an acid group, and the tri- or higher functional ethylenically unsaturated compound in combination, it is more preferable to use the compound M in which the linking group is a linear alkylene group, the compound M having an aliphatic hydrocarbon ring structure, tricyclodecanedimethanol diacrylate, the polyfunctional ethylenically unsaturated compound having a carboxylic acid group, and dipentaerythritol (tri/tetra/penta/hexa)(meth)acrylate in combination, and it is particularly preferable to use 1,9-nonanediol diacrylate, tricyclodecanedimethanol diacrylate, a succinic acid-modified form of dipentaerythritol pentaacrylate, and dipentaerythritol hexaacrylate in combination.

From the viewpoint of water vapor permeability and bendability of the cured product of the photosensitive resin layer, a content of the compound M is preferably 10% by mass to 90% by mass, more preferably 20% by mass to 80% by mass, still more preferably 40% by mass to 75% by mass, and particularly preferably 60% by mass to 70% by mass with respect to the total mass of the ethylenically unsaturated compound in the photosensitive resin composition.

In addition, from the viewpoint of water vapor permeability and bendability of the cured product of the photosensitive resin layer, the content of the compound M is preferably 1% by mass to 45% by mass, more preferably 15% by mass to 40% by mass, still more preferably 20% by mass to 35% by mass, and particularly preferably 25% by mass to 33% by mass with respect to the total solid content in the photosensitive resin composition.

Further, in the photosensitive resin layer or the photosensitive resin composition, as the above-described ethylenically unsaturated compound, from the viewpoint of hardness of the cured film to be obtained, substrate adhesiveness, development residue inhibitory property, and rust preventive property, it is preferable to use the compound M, the ethylenically unsaturated compound having an acid group, the tri- or higher functional ethylenically unsaturated compound, and a thermal crosslinking compound described later in combination, and it is more preferable to use the compound M in which the linking group is a linear alkylene group, the compound M having an aliphatic hydrocarbon ring structure, the ethylenically unsaturated compound having an acid group, the tri- or higher functional ethylenically unsaturated compound, and a blocked isocyanate compound described later in combination.

In addition, in the photosensitive resin layer or the photosensitive resin composition, from the viewpoint of water vapor permeability and bendability of the cured product of the photosensitive resin layer, and pressure-sensitive adhesiveness of the uncured film to be obtained, it is preferable to use the bifunctional ethylenically unsaturated compound having an aliphatic hydrocarbon ring structure and the binder polymer having a constitutional unit having an aliphatic hydrocarbon ring in combination.

<Photopolymerization Initiator>

The photosensitive resin layer or the photosensitive resin composition forming the photosensitive resin layer included in the transfer film according to the embodiment of the present invention may include a photopolymerization initiator.

As the photopolymerization initiator included in the photosensitive resin layer, the same photopolymerization initiator as the photopolymerization initiator included in the composition according to the embodiment of the present invention can be used, and the preferred type is also the same.

In the photosensitive resin layer or the photosensitive resin composition, the photopolymerization initiator may be included alone or in combination of two or more thereof, and it is preferable to be included in combination of two or more thereof.

In the photosensitive resin layer or the photosensitive resin composition, as the photopolymerization initiator, from the viewpoint of substrate adhesiveness, development residue inhibitory property, and rust preventive property, it is preferable to use the oxime-based photopolymerization initiator and the α-aminoalkylphenone-based photopolymerization initiator in combination, and it is more preferable to include 1-[9-ethyl-6-(2-methylbenzoyl)-9H-carbazol-3-yl]ethanone-1-(O-acetyloxime) and 2-methyl-1-(4-methylthiophenyl)-2-morpholinopropan-1-one in combination.

A content of the photopolymerization initiator is not particularly limited, but is preferably 0.1% by mass or more, more preferably 0.5% by mass or more, and still more preferably 1.0% by mass or more with respect to the total solid content of the photosensitive resin layer or the photosensitive resin composition.

In addition, the content of the photopolymerization initiator is preferably 10% by mass or less and more preferably 5% by mass or less with respect to the total solid content of the photosensitive resin layer or the photosensitive resin composition.

<Thermal Crosslinking Compound>

From the reason that punching processability of the cured film obtained by curing the photosensitive resin layer after transfer is better, it is preferable that the photosensitive resin layer or the photosensitive resin composition forming the photosensitive resin layer included in the transfer film according to the embodiment of the present invention contains a compound (hereinafter, also abbreviated as a “thermal crosslinking compound”) that generates, by heating, a group which can react with an acid group or a hydroxy group.

Examples of the thermal crosslinking compound include an epoxy compound, an oxetane compound, a methylol compound, and a blocked isocyanate compound. Among these, from the viewpoint of hardness of the cured film to be obtained and pressure-sensitive adhesiveness of the uncured film to be obtained, a blocked isocyanate compound shown below is preferable.

The blocked isocyanate compound refers to a “compound having a structure in which the isocyanate group of isocyanate is protected (so-called masked) with a blocking agent”.

A dissociation temperature of the blocked isocyanate compound is not particularly limited, but is preferably 100° C. to 160° C. and more preferably 130° C. to 150° C.

Here, the dissociation temperature of blocked isocyanate means “temperature at an endothermic peak accompanied with a deprotection reaction of blocked isocyanate, in a case where the measurement is performed by differential scanning calorimetry (DSC) analysis using a differential scanning calorimeter”.

As the differential scanning calorimeter, for example, a differential scanning calorimeter (model: DSC6200) manufactured by Seiko Instruments Inc. can be suitably used. However, the differential scanning calorimeter is not limited thereto.

Examples of the blocking agent having a dissociation temperature of 100° C. to 160° C. include an active methylene compound [diester malonates (such as dimethyl malonate, diethyl malonate, di-n-butyl malonate, and di-2-ethylhexyl malonate)], and an oxime compound (compound having a structure represented by —C(═N—OH)— in a molecule, such as formaldoxime, acetoaldoxime, acetoxime, methyl ethyl ketoxime, and cyclohexanoneoxime).

Among these, from the viewpoint of storage stability, the blocking agent having a dissociation temperature of 100° C. to 160° C. is preferably, for example, at least one selected from oxime compounds.

From the viewpoint of improving brittleness of the film and improving adhesion to a transferred material, for example, the blocked isocyanate compound preferably has an isocyanurate structure.

The blocked isocyanate compound having an isocyanurate structure can be obtained, for example, by isocyanurate-forming and protecting hexamethylene diisocyanate.

Among the blocked isocyanate compounds having an isocyanurate structure, a compound having an oxime structure using an oxime compound as a blocking agent is preferable from the viewpoint that the dissociation temperature can be easily set in a preferred range and the development residue can be easily reduced, as compared with a compound having no oxime structure.

For example, from the viewpoint of hardness of the cured film obtained by curing the photosensitive resin layer, the blocked isocyanate compound preferably has a polymerizable group and more preferably has a radically polymerizable group.

The polymerizable group is not particularly limited, and a known polymerizable group can be used.

Examples of the polymerizable group include a (meth)acryloxy group, a (meth)acrylamide group, an ethylenically unsaturated bond-containing group such as styryl group, and a group having an epoxy group such as a glycidyl group.

Among these, as the polymerizable group, from the viewpoint of surface shape of the surface of the cured film obtained by curing the photosensitive resin layer, a development speed, and reactivity, an ethylenically unsaturated bond-containing group is preferable, a (meth)acryloxy group is more preferable, and an acryloxy group is particularly preferable.

As the blocked isocyanate compound, a commercially available product can be used.

Examples of the commercially available product of the blocked isocyanate compound include Karenz (registered trademark) AOI-BM, Karenz (registered trademark) MOI-BM, Karenz (registered trademark) MOI-BP, and the like (all of which are manufactured by SHOWA DENKO K.K.), and block-type DURANATE series (for example, DURANATE (registered trademark) TPA-B80E, manufactured by Asahi Kasei Corporation).

The photosensitive resin layer or the photosensitive resin composition may include only one kind of the thermal crosslinking compound, or may include two or more kinds thereof.

In a case of including a thermal crosslinking compound, a content of the thermal crosslinking compound is preferably 1% by mass to 50% by mass and more preferably 5% by mass to 30% by mass with respect to the total solid content of the photosensitive resin layer or the photosensitive resin composition.

<Thiol Compound>

From the reason that punching processability of the cured film obtained by curing the photosensitive resin layer after transfer is better, it is preferable that the photosensitive resin layer or the photosensitive resin composition forming the photosensitive resin layer included in the transfer film contains a compound capable of a Michael addition reaction, and specifically, it is preferable to contain a thiol compound shown below.

As the thiol compound, a monofunctional thiol compound or a polyfunctional thiol compound is preferably used. Among these, from the viewpoint of hardness after curing, the thiol compound preferably contains a bi- or higher functional thiol compound (polyfunctional thiol compound) and is more preferably a polyfunctional thiol compound.

Here, the polyfunctional thiol compound refers to a compound having two or more mercapto groups (thiol groups) in a molecule.

The polyfunctional thiol compound is preferably a low-molecular-weight compound having a molecular weight of 100 or more, and specifically, the molecular weight thereof is more preferably 100 to 1,500 and still more preferably 150 to 1,000.

From the viewpoint of hardness after curing, the number of functional groups in the polyfunctional thiol compound is preferably 2 to 10, more preferably 2 to 8, and still more preferably 2 to 6.

In addition, from viewpoint of tackiness and bendability and hardness after curing, the polyfunctional thiol compound is preferably an aliphatic polyfunctional thiol compound.

Further, from the viewpoint of storage stability of a photosensitive transfer material, the thiol compound is more preferably a secondary thiol compound.

Specific examples of the polyfunctional thiol compound include trimethylolpropane tris(3-mercaptobutyrate), 1,4-bis(3-mercaptobutyryloxy)butane, pentaerythritol tetrakis(3-mercaptobutyrate), 1,3,5-tris(3-mercaptobutyryloxyethyl)-1,3,5-triazine-2,4,6(1H,3H,5H)-trione, trimethylolethane tris(3-mercaptobutyrate), tris[(3-mercaptopropionyloxy)ethyl]isocyanurate, trimethylolpropane tris(3-mercaptopropionate), pentaerythritol tetrakis(3-mercaptopropionate), tetraethylene glycol bis(3-mercaptopropionate), dipentaerythritol hexakis(3-mercaptopropionate), ethylene glycol bisthiopropionate, 1,2-benzenedithiol, 1,3-benzenedithiol, 1,2-ethanedithiol, 1,3-propanedithiol, 1,6-hexamethylenedithiol, 2,2′-(ethylenedithio)diethanethiol, meso-2,3-dimercaptosuccinic acid, p-xylylenedithiol, m-xylylenedithiol, and di(mercaptoethyl)ether.

Among these, preferred examples thereof include trimethylolpropane tris(3-mercaptobutyrate), 1,4-bis(3-mercaptobutyryloxy)butane, pentaerythritol tetrakis(3-mercaptobutyrate), 1,3,5-tris(3-mercaptobutyryloxyethyl)-1,3,5-triazine-2,4,6(1H,3H,5H)-trione, trimethylolethane tris(3-mercaptobutyrate), tris[(3-mercaptopropionyloxy)ethyl]isocyanurate, trimethylolpropane tris(3-mercaptopropionate), pentaerythritol tetrakis(3-mercaptopropionate), tetraethylene glycol bis(3-mercaptopropionate), and dipentaerythritol hexakis(3-mercaptopropionate).

As the monofunctional thiol compound, both an aliphatic thiol compound and an aromatic thiol compound can be used.

Specific examples of the monofunctional aliphatic thiol compound include 1-octanethiol, 1-dodecanethiol, β-mercaptopropionic acid, methyl-3-mercaptopropionate, 2-ethylhexyl-3-mercaptopropionate, n-octyl-3-mercaptopropionate, methoxybutyl-3-mercaptopropionate, and stearyl-3-mercaptopropionate.

Examples of the monofunctional aromatic thiol compound include benzenethiol, toluenethiol, and xylenethiol.

From the viewpoint of tackiness, bendability and hardness after curing, the thiol compound is preferably a thiol compound having an ester bond, and more preferably includes a compound represented by Formula 1.

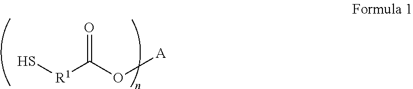

In Formula 1, n represents an integer of 1 to 6, A represents an n-valent organic group having 1 to 15 carbon atoms or a group represented by Formula 2, and R¹'s each independently represent a divalent organic group having 1 to 15 carbon atoms.

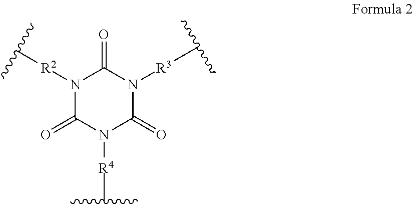

In Formula 2, R² to R⁴ each independently represent a divalent organic group having 1 to 15 carbon atoms, and wavy line parts represent bonding positions to an oxygen atom adjacent to A in Formula 1. However, in a case where A represents the group represented by Formula 2, n represents 3.

From the viewpoint of hardness after curing, n in Formula 1 is preferably an integer of 2 to 6.

From the viewpoint of tackiness, and bendability and hardness after curing, A in Formula 1 is preferably an n-valent aliphatic group having 1 to 15 carbon atoms or the group represented by Formula 2, more preferably an n-valent aliphatic group having 4 to 15 carbon atoms or the group represented by Formula 2, still more preferably an n-valent aliphatic group having 4 to 10 carbon atoms or the group represented by Formula 2, and particularly preferably the group represented by Formula 2.

In addition, from the viewpoint of tackiness, bendability, and hardness, and moisture permeability after curing, A in Formula 1 is preferably an n-valent group consisting of a hydrogen atom and a carbon atom or an n-valent group consisting of a hydrogen atom, a carbon atom, and an oxygen atom, more preferably an n-valent group consisting of a hydrogen atom and a carbon atom, and particularly preferably an n-valent aliphatic hydrocarbon group.

From the viewpoint of tackiness, bendability, and hardness after curing, R's in Formula 1 are each independently preferably an alkylene group having 1 to 15 carbon atoms, more preferably an alkylene group having 2 to 4 carbon atoms, still more preferably an alkylene group having 3 carbon atoms, and particularly preferably a 1,2-propylene group.

The alkylene group may be linear or branched.

From the viewpoint of tackiness, bendability, and hardness after curing, R² to R⁴ in Formula 2 are each independently preferably an aliphatic group having 2 to 15 carbon atoms, more preferably an alkylene group having 2 to 15 carbon atoms or a polyalkyleneoxyalkyl group having 3 to 15 carbon atoms, still more preferably an alkylene group having 2 to 15 carbon atoms, and particularly preferably an ethylene group.

In addition, as the polyfunctional thiol compound, a compound having two or more groups represented by Formula S-1 is preferable.

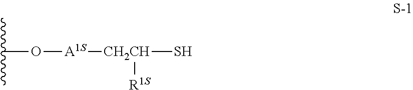

In Formula S-1, R^{1S} represents a hydrogen atom or an alkyl group, A^{1S} represents —CO— or —CH₂—, and wavy line parts represent bonding positions to another structure.

The polyfunctional thiol compound is preferably a compound having 2 to 6 groups represented by Formula S-1.

The alkyl group of R^{1S} in Formula S-1 is a linear, branched, or cyclic alkyl group, and the range of the number of carbon atoms is preferably 1 to 16 and more preferably 1 to 10.

Specific examples of the alkyl group include a methyl group, an ethyl group, a propyl group, an isopropyl group, a butyl group, an isobutyl group, an s-butyl group, a t-butyl group, a pentyl group, a hexyl group, and a 2-ethylhexyl group, and a methyl group, an ethyl group, a propyl group, or an isopropyl group is preferable.

As R^{1S}, a hydrogen atom, a methyl group, an ethyl group, a propyl group, or an isopropyl group is particularly preferable, and a methyl group or an ethyl group is most preferable.

Further, the polyfunctional thiol compound is particularly preferably a compound represented by Formula S-2, which has a plurality of groups represented by Formula S-1.

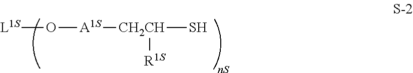

In Formula S-2, R^{1S}'s each independently represent a hydrogen atom or an alkyl group, A^{1S}'s each independently represent —CO— or —CH₂—, L^{1S} represents an nS-valent linking group, and nS represents an integer of 2 to 8. From the viewpoint of synthesis, it is preferable that all R^{1S}'s have the same group, and it is preferable that all A^{1S}'s have the same group.

R^{1S} in Formula S-2 is the same as R^{1S} in Formula S-1, and the preferred range thereof is also the same. nS is preferably an integer of 2 to 6.

Examples of L^{1S}, which is an nS-valent linking group in Formula S-2, include a divalent linking group such as —(CH₂)_{mS}— (mS represents an integer of 2 to 6) or —(CH₂)_{mS}{(CH₂)_{mS}O}_{mT}(CH₂)_{mS}— (mS and mT each independently represent an integer of 2 to 6), a trivalent linking group such as a trimethylolpropane residue, isocyanuric ring having three of —(CH₂)_{pS}-(pS represents an integer of 2 to 6), a tetravalent linking group such as a pentaerythritol residue, and a pentavalent or hexavalent linking group such as a dipentaerythritol residue.

Specific examples of the thiol compound preferably include the following compounds, but the thiol compound is not limited thereto.

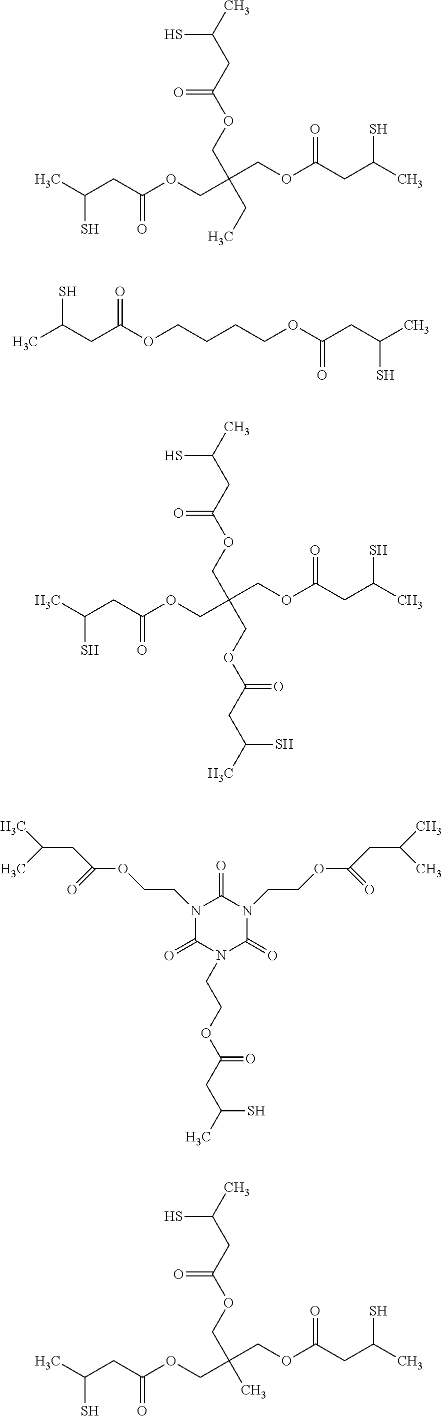

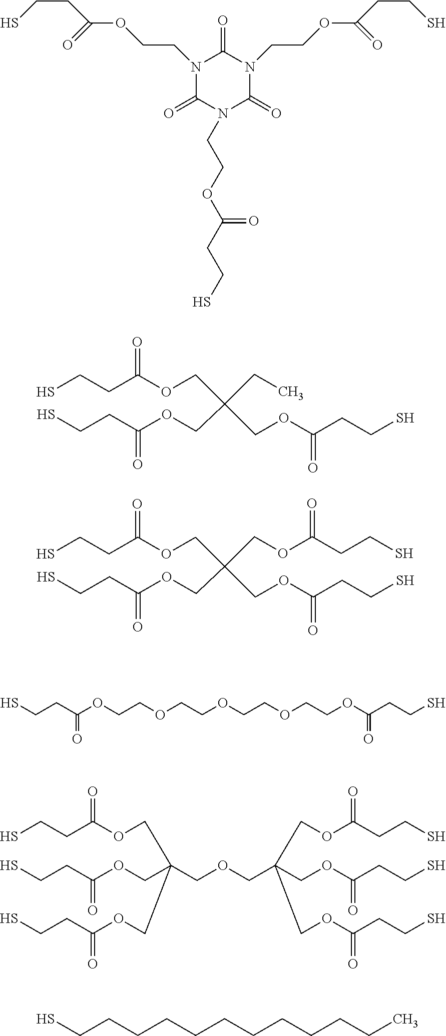

<Heterocyclic Compound>

The photosensitive resin layer or the photosensitive resin composition forming the photosensitive resin layer included in the transfer film according to the embodiment of the present invention preferably contains a heterocyclic compound.

The heterocyclic compound contributes to improvement of adhesiveness to a base material (particularly, a copper substrate) and corrosion inhibitory property of the metal (particularly, copper).

A heterocyclic ring included in the heterocyclic compound may be a monocyclic or polycyclic heterocyclic ring.

Examples of a heteroatom included in the heterocyclic compound include an oxygen atom, a nitrogen atom, and a sulfur atom. The heterocyclic compound preferably has at least one atom selected from the group consisting of a nitrogen atom, an oxygen atom, and a sulfur atom, and more preferably has a nitrogen atom.

Preferred examples of the heterocyclic compound include a triazole compound, a benzotriazole compound, a tetrazole compound, a thiadiazole compound, a triazine compound, a rhodanine compound, a thiazole compound, a benzothiazole compound, a benzimidazole compound, a benzoxazole compound, and a pyrimidine compound. Among the above, the heterocyclic compound is preferably at least one compound selected from the group consisting of a triazole compound, a benzotriazole compound, a tetrazole compound, a thiadiazole compound, a triazine compound, a rhodanine compound, a thiazole compound, a benzimidazole compounds, and a benzoxazole compound, and more preferably at least one compound selected from the group consisting of a triazole compound, a benzotriazole compound, a tetrazole compound, a thiadiazole compound, a thiazole compound, a benzothiazole compound, a benzimidazole compound, and a benzoxazole compound.

Preferred specific examples of the heterocyclic compound are shown below. Examples of the triazole compound and the benzotriazole compound include the following compounds.

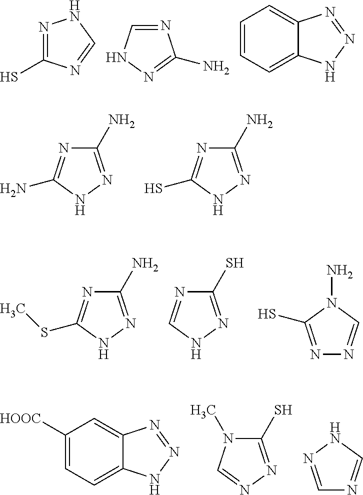

Examples of the tetrazole compound include the following compounds.

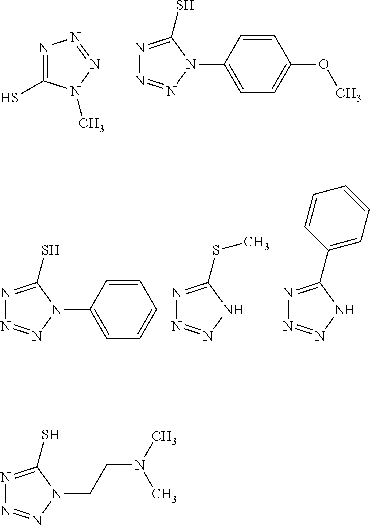

Examples of the thiadiazole compound include the following compounds.

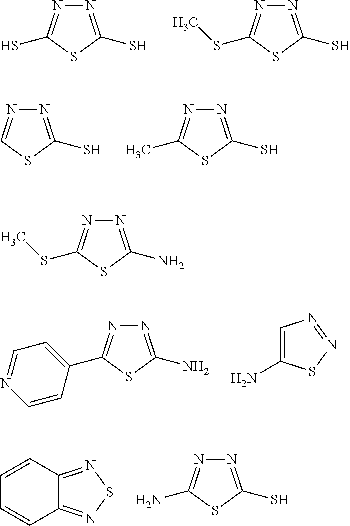

Examples of the triazine compound include the following compounds.

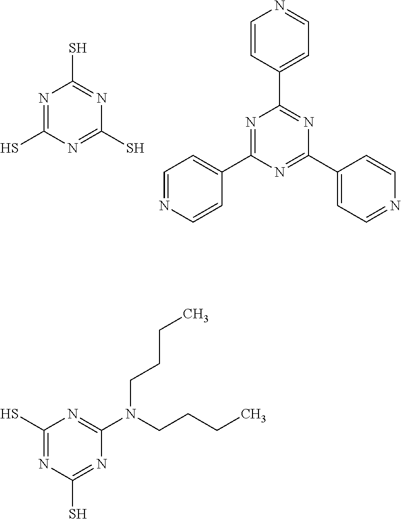

Examples of the rhodanine compound include the following compounds.

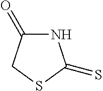

Examples of the thiazole compound include the following compounds.

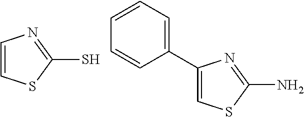

Examples of the benzothiazole compound include the following compounds.

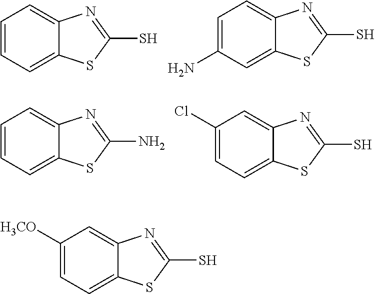

Examples of the benzimidazole compound include the following compounds.

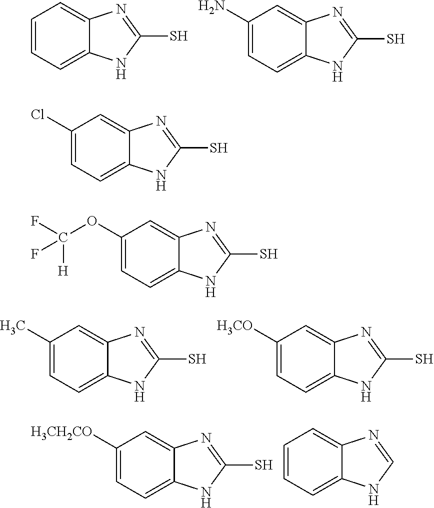

Examples of the benzoxazole compound include the following compounds.

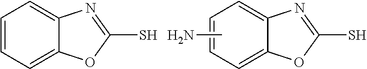

The photosensitive resin layer or the photosensitive resin composition may include only one kind of the heterocyclic compound, or may include two or more kinds thereof.

In a case of containing a heterocyclic compound, a content of the heterocyclic compound is preferably 0.01% by mass to 20% by mass, more preferably 0.1% by mass to 10% by mass, still more preferably 0.3% by mass to 8% by mass, and particularly preferably 0.5% by mass to 5% by mass with respect to the total solid content of the photosensitive resin layer or the photosensitive resin composition. In a case where the content of the heterocyclic compound is within the above-described range, the adhesiveness to the base material (particularly, a copper substrate) and the corrosion inhibitory property of the metal (particularly, copper) can be improved.

<Surfactant>

The photosensitive resin layer or the photosensitive resin composition forming the photosensitive resin layer included in the transfer film according to the embodiment of the present invention may include a surfactant.

As the surfactant included in the photosensitive resin layer, the same surfactant as the surfactant included in the refractive index adjusting layer can be used, and the preferred range thereof is also the same.

<Hydrogen Donating Compound>

The photosensitive resin layer or the photosensitive resin composition forming the photosensitive resin layer included in the transfer film according to the embodiment of the present invention preferably includes a hydrogen donating compound.

Here, the hydrogen donating compound has a function of further improving sensitivity of the photopolymerization initiator to actinic ray, or suppressing inhibition of polymerization of the polymerizable compound by oxygen.

Examples of such a hydrogen donating compound include amines, for example, compounds described in M. R. Sander et al., “Journal of Polymer Society” Vol. 10, page 3173 (1972), JP1969-20189B (JP-S44-20189B), JP1976-82102A (JP-S51-82102A), JP1977-134692A (JP-S52-134692A), JP1984-138205A (JP-S59-138205A), JP1985-84305A (JP-S60-84305A), JP1987-18537A (JP-S62-18537A), JP1989-33104A (JP-S64-33104A), and Research Disclosure 33825.

Specific examples of the hydrogen donating compound include triethanolamine, p-dimethylaminobenzoic acid ethyl ester, p-formyldimethylaniline, and p-methylthiodimethylaniline.

In addition, examples of the hydrogen donating compound also include an amino acid compound (N-phenylglycine and the like), an organic metal compound described in JP1973-42965B (JP-S48-42965B) (tributyl tin acetate and the like), a hydrogen donor described in JP1980-34414B (JP-S55-34414B), and a sulfur compound described in JP1994-308727A (JP-H6-308727A) (trithiane and the like).

The photosensitive resin layer or the photosensitive resin composition may include only one kind of the hydrogen donating compound, or may include two or more kinds thereof.

In a case of including a hydrogen donating compound, for example, from the viewpoint of improving a curing rate by balancing the polymerization growth rate and chain transfer, a content of the hydrogen donating compound is preferably 0.01% by mass to 10% by mass, more preferably 0.03% by mass to 5% by mass, and still more preferably 0.05% by mass to 3% by mass with respect to the total solid content of the photosensitive resin layer or the photosensitive resin composition.

<Solvent>

The photosensitive resin composition forming the photosensitive resin layer included in the transfer film according to the embodiment of the present invention preferably includes a solvent.

In a case where the photosensitive resin composition includes a solvent, the formation of the photosensitive resin layer by coating tends to be easier.

As the solvent included in the photosensitive resin layer, the same solvent as the solvent included in the composition according to the embodiment of the present invention can be used, and the preferred range thereof is also the same. In a case where the photosensitive resin composition includes a solvent, a solid content of the photosensitive resin composition is preferably 5% by mass to 80% by mass, more preferably 5% by mass to 40% by mass, and particularly preferably 5% by mass to 30% by mass with respect to the total mass of the photosensitive resin composition.

<Other Components>

The photosensitive resin layer or the photosensitive resin composition forming the photosensitive resin layer included in the transfer film according to the embodiment of the present invention may include a component other than the above-described components (so-called other components).

Examples of the other components include particles (for example, metal oxide particles) and a colorant.

In addition, examples of the other components include a thermal polymerization inhibitor described in paragraph 0018 of JP4502784B and other additives described in paragraphs 0058 to 0071 of JP2000-310706A.

—Particles—

For the purpose of adjusting refractive index, light-transmitting property, and the like, the photosensitive resin layer or the photosensitive resin composition may include particles (for example, metal oxide particles; the same applies hereinafter).

A metal of the metal oxide particles also includes semimetal such as B, Si, Ge, As, Sb, or Te.

From the viewpoint of transparency of the cured film, for example, an average primary particle diameter of the particles is preferably 1 nm to 200 nm and more preferably 3 nm to 80 nm.

The average primary particle diameter of the particles is calculated by measuring particle diameters of 200 random particles using an electron microscope and arithmetically averaging the measurement result. In a case where a shape of the particle is not a spherical shape, the longest side is set as the particle diameter.

In a case where the photosensitive resin layer or the photosensitive resin composition includes particles, the photosensitive resin layer or the photosensitive resin composition may include only one kind of particles having different metal types, sizes, and the like, or may include two or more kinds thereof.

It is preferable that the photosensitive resin layer or the photosensitive resin composition does not include particles, or the content of the particles is more than 0% by mass to 35% by mass or less with respect to the total solid content of the photosensitive resin composition; it is more preferable that the photosensitive resin layer or the photosensitive resin composition does not include particles, or the content of the particles is more than 0% by mass to 10% by mass or less with respect to the total solid content of the photosensitive resin composition; it is still more preferable that the photosensitive resin layer or the photosensitive resin composition does not include particles, or the content of the particles is more than 0% by mass to 5% by mass or less with respect to the total solid content of the photosensitive resin composition; it is even more preferable that the photosensitive resin layer or the photosensitive resin composition does not include particles, or the content of the particles is more than 0% by mass to 1% by mass or less with respect to the total solid content of the photosensitive resin composition; and it is particularly preferably that the photosensitive resin layer or the photosensitive resin composition does not include particles.

In a case where a transfer film having a photosensitive resin layer including no particles is used, it is possible to further prevent air bubbles from being mixed during transfer of the transfer film.

—Colorant—

The photosensitive resin layer or photosensitive resin composition may include a trace amount of a colorant (pigment, dye, and the like), but for example, from the viewpoint of transparency, it is preferable that the photosensitive resin layer or photosensitive resin composition does not substantially include the colorant.

In a case of including a colorant, a content of the colorant is preferably less than 1% by mass and more preferably less than 0.1% by mass with respect to the total solid content of the photosensitive resin layer or the photosensitive resin composition.

<Thickness of Photosensitive Resin Layer>

A thickness of the photosensitive resin layer is not particularly limited, but is preferably 20 μm or less, more preferably 15 μm or less, and still more preferably 12 μm or less.

The case where the thickness of the photosensitive resin layer is 20 μm or less is advantageous from the viewpoint of reducing the thickness of the entire transfer film, improving transmittance of the photosensitive resin layer or the cured film to be obtained, and preventing yellowing of the photosensitive resin layer or the cured film to be obtained.

For example, from the viewpoint of manufacturing suitability, the thickness of the photosensitive resin layer is preferably 1 μm or more, more preferably 2 μm or more, and particularly preferably 3 μm or more.

The thickness of the photosensitive resin layer is obtained as an average value of 5 random points measured by cross-sectional observation with a scanning electron microscope (SEM).

<Refractive Index of Photosensitive Resin Layer>

A refractive index of the photosensitive resin layer is not particularly limited, but is preferably 1.47 to 1.56, more preferably 1.50 to 1.53, still more preferably 1.50 to 1.52, and particularly preferably 1.51 to 1.52.

<Forming Method of Photosensitive Resin Layer>

A forming method of the photosensitive resin layer is not particularly limited, and a known method can be used.

As an example of the forming method of the photosensitive resin layer, a method of forming the photosensitive resin layer by applying a photosensitive resin composition including a solvent onto a temporary support and then drying, as necessary is used.

Specific examples of coating and drying methods in the forming method of the photosensitive resin layer are the same as the specific examples of coating and drying in the forming method of the refractive index adjusting layer, respectively.

[Color of Photosensitive Resin Layer]

The photosensitive resin layer is preferably achromatic. Specifically, in CIE1976 (L*, a*, b*) color space of the total reflection (incidence angle: 8°, light source: D-65 (visual field: 2°)), the L* value is preferably 10 to 90, the a* value is preferably −1.0 to 1.0, and the b* value is preferably −1.0 to 1.0.

[Protective Film]

The transfer film according to the embodiment of the present invention preferably has a protective film.

Examples of the protective film include a polyethylene terephthalate film, a polypropylene film, a polyethylene film, a polystyrene film, and a polycarbonate film.

As the protective film, for example, films described in paragraphs 0083 to 0087 and 0093 of JP2006-259138A may be used.

The protective film is also available as, for example, ALPHAN (registered trademark) FG-201 and ALPHAN (registered trademark) E-201F manufactured by Oji F-Tex Co., Ltd., Cerapeel (registered trademark) 25WZ manufactured by TORAY ADVANCED FILM CO., LTD., and LUMIRROR (registered trademark) 16QS62 manufactured by Toray Industries, Inc.

In addition, the protective film preferably has 5 pieces/m² or less of the number of fisheyes with a diameter of 80 μm or more in the protective film. The “fisheye” means that, in a case where a material is hot-melted, kneaded, extruded, biaxially stretched, cast or the like to produce a film, foreign substances, undissolved substances, oxidatively deteriorated substances, and the like of the material are incorporated into the film.

The number of particles having a diameter of 3 μm or more included in the protective film is preferably 30 particles/mm² or less, more preferably 10 particles/mm² or less, and still more preferably 5 particles/mm² or less. As a result, it is possible to suppress defects caused by ruggedness due to the particles included in the protective film being transferred to the photosensitive resin layer.

In the protective film, from the viewpoint of imparting take-up property, an arithmetic average roughness Ra on a surface opposite to a surface in contact with the refractive index adjusting layer is preferably 0.01 μm or more, more preferably 0.02 μm or more, and still more preferably 0.03 μm or more. On the other hand, it is preferable to be less than 0.50 μm, it is more preferable to be 0.40 μm or less, and it is still more preferable to be 0.30 μm or less.

In the protective film, from the viewpoint of suppressing defects during transfer, the arithmetic average roughness Ra on the surface in contact with the refractive index adjusting layer is preferably 0.01 μm or more, more preferably 0.02 μm or more, and still more preferably 0.03 μm or more. On the other hand, it is preferable to be less than 0.50 μm, it is more preferable to be 0.40 μm or less, and it is still more preferable to be 0.30 μm or less.

In the present invention, from the viewpoint of adjusting the arithmetic average roughness Ra of the surface of the protective film on the refractive index adjusting layer side to the above-described range, the protective film may contain particles, and as a layer structure included in the temporary support, a particle-containing layer constituting the surface on the refractive index adjusting layer side may be provided.

Examples of the particles contained in the protective film (particularly, the particle-containing layer) include particles same as those exemplified as the particles contained in the temporary support.

[Thermoplastic Resin Layer]

The transfer film according to the embodiment of the present invention may further have a thermoplastic resin layer between the temporary support and the refractive index adjusting layer or between the temporary support and the photosensitive resin layer.

In a case where the transfer film further has a thermoplastic resin layer, air bubbles due to lamination are hardly generated in a case where the transfer film is transferred to a substrate to form a laminate. In a case where this laminate is used in an image display apparatus, image unevenness and the like are hardly generated and excellent display properties are obtained.

The thermoplastic resin layer preferably has alkali solubility.

The thermoplastic resin layer functions as a cushion material which absorbs ruggedness of the surface of the substrate in a case of transfer.

The ruggedness of the surface of the substrate includes an image, an electrode, a wiring, and the like which are formed in advance.

The thermoplastic resin layer preferably has properties capable of being deformed in accordance with ruggedness.

The thermoplastic resin layer preferably includes an organic polymer substance described in JP1993-72724A (JP-H5-72724A), and more preferably includes an organic polymer substance having a softening point approximately 80° C. or lower by a Vicat method (specifically, polymer softening point measurement method using an American Society for Testing and Materials (ASTM International) ASTM D 1235).

A thickness of the thermoplastic resin layer is preferably 3 μm to 30 μm, more preferably 4 μm to 25 μm, and still more preferably 5 μm to 20 μm.

In a case where the thickness of the thermoplastic resin layer is 3 μm or more, followability with respect to the ruggedness of the surface of the substrate is improved, and the ruggedness of the surface of the substrate can be effectively absorbed.

In a case where the thickness of the thermoplastic resin layer is 30 μm or less, since the manufacturing suitability is more improved, for example, burden of the drying (so-called drying for removing the solvent) in a case of applying and forming the thermoplastic resin layer on the temporary support is further reduced, and the development time of the thermoplastic resin layer after the transfer is further shortened.

The thickness of the thermoplastic resin layer is obtained as an average value of 5 random points measured by cross-sectional observation with a scanning electron microscope (SEM).

The thermoplastic resin layer can be formed by applying and, as necessary, drying a composition for forming a thermoplastic resin layer including a solvent and a thermoplastic organic polymer on the temporary support.

Specific examples of coating and drying methods in the forming method of the thermoplastic resin layer are the same as the specific examples of coating and drying in the forming method of the photosensitive resin layer, respectively.

The solvent is not particularly limited as long as the solvent dissolves polymer components forming the thermoplastic resin layer.

Examples of the solvent include organic solvents (for example, methyl ethyl ketone, cyclohexanone, propylene glycol monomethyl ether acetate, n-propanol, and 2-propanol).

A viscosity of the thermoplastic resin layer measured at 100° C. is preferably 1,000 Pa·s to 10,000 Pa·s. In addition, the viscosity of the thermoplastic resin layer measured at 100° C. is preferably lower than the viscosity of the photosensitive resin layer measured at 100° C.

[Interlayer]

The transfer film according to the embodiment of the present invention may further have an interlayer between the temporary support and the refractive index adjusting layer or between the temporary support and the photosensitive resin layer.

In a case where the transfer film according to the embodiment of the present invention has the thermoplastic resin layer, the interlayer is preferably disposed between the thermoplastic resin layer and the photosensitive resin layer.

Examples of a component included in the interlayer include at least one polymer selected from the group consisting of polyvinyl alcohol, polyvinylpyrrolidone, and cellulose.

In addition, as the interlayer, a component described in JP1993-72724A (JP-H5-72724A) as a “separation layer” can also be used.

In a case of producing the transfer film having the thermoplastic resin layer, the interlayer, the photosensitive resin layer, and the refractive index adjusting layer on the temporary support in this order, for example, the interlayer can be formed by applying and, as necessary, drying a composition for forming an interlayer including a solvent which does not dissolve the thermoplastic resin layer, and the above-described polymer as the component of the interlayer. Specifically, first, the composition for forming a thermoplastic resin layer is applied and dried on the temporary support to form the thermoplastic resin layer. Next, the composition for forming an interlayer is applied on the formed thermoplastic resin layer and dried as necessary to form the interlayer. Next, a photosensitive resin composition (so-called a composition for forming a photosensitive resin layer) including an organic solvent is applied on the formed interlayer and dried to form the photosensitive resin layer. The organic solvent included in the composition for forming a photosensitive resin layer is preferably an organic solvent which does not dissolve the interlayer. Next, the composition according to the embodiment of the present invention (so-called a composition for forming a refractive index adjusting layer) including an aqueous solvent is applied on the formed photosensitive resin layer and dried to form the refractive index adjusting layer. The aqueous solvent included in the composition according to the embodiment of the present invention is preferably an aqueous solvent which does not dissolve the photosensitive resin layer.

On the other hand, in a case of producing the transfer film having the thermoplastic resin layer, the interlayer, and the single-layer refractive index adjusting layer on the temporary support in this order, first, the composition for forming a thermoplastic resin layer is applied and dried on the temporary support to form the thermoplastic resin layer. Next, the composition for forming an interlayer is applied on the formed thermoplastic resin layer and dried as necessary to form the interlayer. Next, the composition according to the embodiment of the present invention (so-called a composition for forming a refractive index adjusting layer) including an organic solvent is applied on the formed interlayer and dried to form the refractive index adjusting layer. The organic solvent included in the composition according to the embodiment of the present invention is preferably an organic solvent which does not dissolve the interlayer.

Specific examples of coating and drying methods in the forming method of the interlayer are the same as the specific examples of coating and drying in the forming method of the refractive index adjusting layer, respectively.

[Specific Example of Transfer Film]

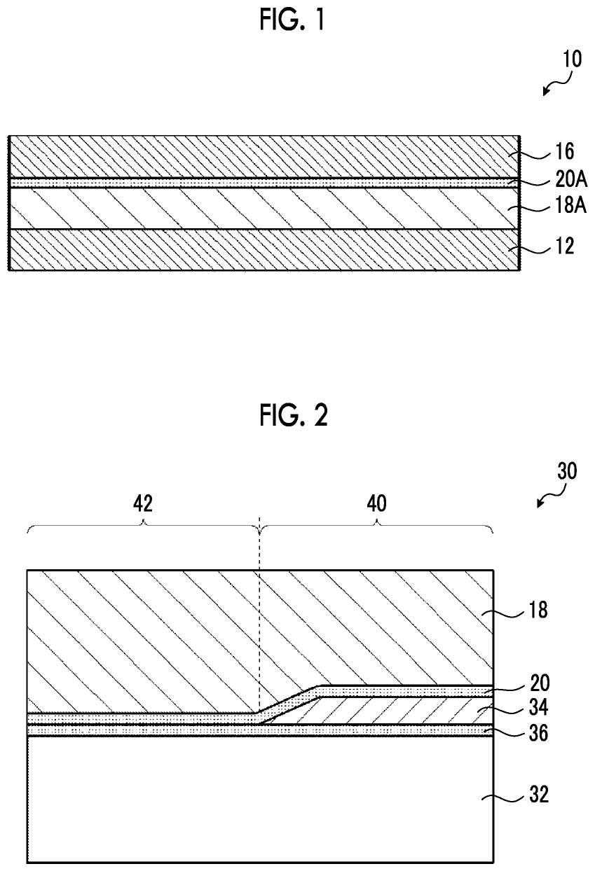

FIG. 1 is a schematic cross-sectional view showing an example of the transfer film according to the embodiment of the present invention.

As shown in FIG. 1, a transfer film 10 has a laminated structure of protective film 16/refractive index adjusting layer 20A/photosensitive resin layer 18A/temporary support 12 (that is, laminated structure in which a temporary support 12, a photosensitive resin layer 18A, a refractive index adjusting layer 20A, and a protective film 16 are arranged in this order).

However, the transfer film according to the embodiment of the present invention is not limited to the transfer film 10, and for example, the photosensitive resin layer 18A may be omitted. In addition, at least one of the thermoplastic resin layer or the interlayer described above may be provided between the temporary support 12 and the photosensitive resin layer 18A.

The refractive index adjusting layer 20A is a layer disposed on a side opposite to the side where the temporary support 12 exists as seen from the photosensitive resin layer 18A.

The refractive index adjusting layer 20A is preferably a layer having a refractive index at a wavelength of 550 nm of 1.50 or more.

The transfer film 10 is a negative type material (so-called negative type film).

[Manufacturing Method of Transfer Film]

A manufacturing method of the transfer film 10 is not particularly limited.

In the case where a single-layer refractive index adjusting layer formed of a cured product of the composition according to the embodiment of the present invention can be used as a protective film in a touch panel, the manufacturing method of the transfer film 10 preferably includes, for example, a step of forming the refractive index adjusting layer 20a on the temporary support 12 and a step of forming the protective film 16 on the refractive index adjusting layer 20A, in this order.

In the case where a cured product of the composition according to the embodiment of the present invention is used as a refractive index adjusting layer (that is, the case where a separately prepared cured product of a photosensitive resin layer can be used as a protective film in a touch panel), the manufacturing method of the transfer film 10 preferably includes a step of forming the photosensitive resin layer 18A on the temporary support 12, a step of forming the refractive index adjusting layer 20A on the photosensitive resin layer 18A, and a step of forming the protective film 16 on the refractive index adjusting layer 20A, in this order.

The manufacturing method of the transfer film 10 may include a step of volatilizing ammonia described in a paragraph 0056 of WO2016/009980A, between the step of forming the refractive index adjusting layer 20A and the step of forming the protective film 16.

[Use]

The use of the transfer film according to the embodiment of the present invention is not particularly limited, but since the bendability is excellent, the transfer film according to the embodiment of the present invention can be suitably used as a transfer film for a touch panel, more suitably used as a transfer film for forming a protective film in a touch panel, and particularly suitably used as a transfer film for forming an electrode protective film in a touch panel.

<Laminate>

By using the transfer film according to the embodiment of the present invention, the refractive index adjusting layer of the transfer film according to the embodiment of the present invention is transferred onto a substrate having an electrode, and a laminate in which a cured film obtained by curing the refractive index adjusting layer is laminated can be manufactured.

For example, in a case where the transfer film according to the embodiment of the present invention has a protective film, a manufacturing method of the laminate preferably includes a first peeling step of peeling off the protective film from the above-described transfer film according to the embodiment of the present invention, a transfer step of transferring the transfer film from which the protective film has been peeled off onto a substrate having an electrode from the refractive index adjusting layer side, a curing step of curing at least a part of the transferred refractive index adjusting layer to form a cured film, and a second peeling step of peeling off the temporary support after the curing step to obtain a laminate in which the cured film is laminated on the substrate having an electrode.

Examples of specific methods in the first peeling step, transfer step, and second peeling step of the manufacturing method of the laminate include the same methods as those described in the first peeling step, transfer step, and second peeling step of a manufacturing method of a touch panel according to an embodiment of the present invention described later.

The substrate having an electrode is preferably a substrate including an electrode of the electrostatic capacity-type input device.

In addition, the electrode of the electrostatic capacity-type input device may be a transparent electrode pattern or a lead wire.

<Touch Panel>

The laminate can be used as a member of the electrostatic capacity-type input device.

As the electrostatic capacity-type input device, a touch panel is suitably used. The laminate is preferably used as a touch panel member.

As an electrode for a touch panel, a transparent electrode pattern disposed at least in an image display region of the touch panel is used. The electrode for a touch panel may extend from the image display region to a frame portion of the touch panel.

As a wire for a touch panel, a lead wire (so-called lead-out wire) disposed on the frame portion of the touch panel is used.

As an aspect of the substrate for a touch panel and the touch panel, an aspect in which the transparent electrode pattern and the lead wire are electrically connected to each other by laminating a part of the lead wire on a portion of the transparent electrode pattern extending to the frame portion of the touch panel is suitable.

As a material of the transparent electrode pattern, a metal oxide film such as indium tin oxide (ITO) and indium zinc oxide (IZO), or a fine metal wire such as metal mesh and silver nanowire is preferable.

Examples of the fine metal wire include thin wire of silver and copper. Among these, silver conductive materials such as silver mesh and silver nanowire are preferable.

As a material of the lead wire, metal is preferable.

Examples of a metal which is the material of the lead wire include gold, silver, copper, molybdenum, aluminum, titanium, chromium, zinc, manganese, and alloy consisting of two or more kinds of these metal elements. As the material of the lead wire, copper, molybdenum, aluminum, or titanium is preferable, copper is particularly preferable.

<First Specific Example of Touch Panel>

FIG. 2 is a schematic cross-sectional view showing a first specific example of a touch panel having a cured film (cured product of the refractive index adjusting layer) formed by transferring and curing with the transfer film according to the embodiment of the present invention. More specifically, FIG. 2 is a schematic cross-sectional view of an image display region of a touch panel 30.

As shown in FIG. 2, the touch panel 30 has a structure in which a substrate 32, a second refractive index adjusting layer 36, a transparent electrode pattern 34 as the electrode for a touch panel, a cured film 20 (cured product of the refractive index adjusting layer) as a first refractive index adjusting layer, and an electrode protective film 18 for a touch panel are disposed in this order.

In the touch panel 30, the electrode protective film 18 for a touch panel and the cured film 20 cover the entire transparent electrode pattern 34.

It is preferable that the second refractive index adjusting layer 36 and the cured film 20 are continuously coated over a first region 40 in which the transparent electrode pattern 34 is present and a second region 42 in which the transparent electrode pattern 34 is not present directly or through another layer, respectively. According to such an aspect, the transparent electrode pattern 34 is less visible.

It is preferable that the second refractive index adjusting layer 36 and the cured film 20 are directly coated over both of the first region 40 and the second region 42, rather than the coating through other layer.

Examples of the “other layer” include an insulating layer and an electrode pattern other than the transparent electrode pattern 34.

The cured film 20 is laminated over both of the first region 40 and the second region 42. The cured film 20 is adjacent to the second refractive index adjusting layer 36 and is also adjacent to the transparent electrode pattern 34.

In a case where the shape of the end part of the transparent electrode pattern 34 at a portion in contact with the second refractive index adjusting layer 36 is a tapered shape as shown in FIG. 2, the cured film 20 is preferably laminated along the tapered shape (that is, at the same tilt as the taper angle).

As the transparent electrode pattern 34, an ITO transparent electrode pattern is suitable.

The transparent electrode pattern 34 can be, for example, formed by the following method.

A thin film for an electrode (for example, an ITO film) is formed on the substrate 32 on which the second refractive index adjusting layer 36 is formed by sputtering. Next, by applying a photosensitive resist for etching or transferring a photosensitive film for etching on the formed thin film for an electrode, an etching protective layer is formed. Next, the formed etching protective layer is patterned into a desired patterned shape by exposure and development. Next, a portion of the thin film for an electrode which is not covered with the patterned etching protective layer is removed by etching to form the thin film for an electrode into a pattern having a desired shape (that is, the transparent electrode pattern 34). Next, the patterned etching protective layer is removed by a stripper.

<Second Specific Example of Touch Panel>

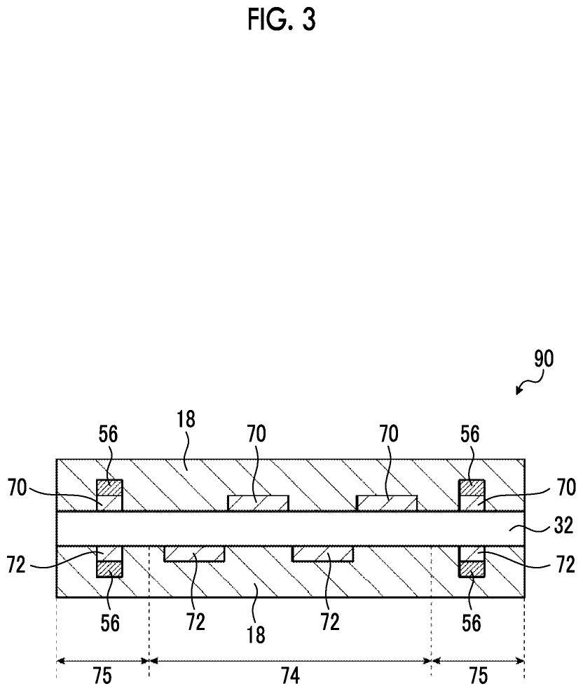

FIG. 3 is a schematic cross-sectional view showing a second specific example of a touch panel having a cured film (cured product of the refractive index adjusting layer; not shown in FIG. 3) and a cured product of the photosensitive resin layer, which are formed by transferring and curing with the transfer film according to the embodiment of the present invention.

As shown in FIG. 3, the touch panel 90 has an image display region 74 and an image non-display region 75 (that is, frame portion).

In addition, the touch panel 90 includes the electrode for a touch panel on both surfaces of a substrate 32. Specifically, the touch panel 90 includes a first transparent electrode pattern 70 on one surface of the substrate 32 and includes a second transparent electrode pattern 72 on the other surface thereof.

In the touch panel 90, a lead wire 56 is connected to the first transparent electrode pattern 70 and the second transparent electrode pattern 72, respectively. The lead wire 56 is, for example, a copper wire.

In the touch panel 90, the cured film (not shown) (cured product of the refractive index adjusting layer, that is, first refractive index adjusting layer) and the electrode protective film 18 for a touch panel are formed on one surface of the substrate 32 so as to cover the first transparent electrode pattern 70 and the lead wire 56, and the cured film (not shown) (cured product of the refractive index adjusting layer, that is, first refractive index adjusting layer) and the electrode protective film 18 for a touch panel are formed on the other surface of the substrate 32 so as to cover the second transparent electrode pattern 72 and the lead wire 56.

The second refractive index adjusting layers of the first specific example may be formed on the one surface and the other surface of the substrate 32, respectively.

[Manufacturing Method of Touch Panel]

A manufacturing method of a touch panel according to an embodiment of the present invention includes a step of preparing a substrate for a touch panel having a structure in which at least one of an electrode for a touch panel or a wire for a touch panel is disposed on a substrate, a step of forming a refractive index adjusting layer consisting of the composition according to the embodiment of the present invention or a refractive index adjusting layer obtained by drying the composition on a surface of the substrate for a touch panel, on a side on which at least one of the electrode for a touch panel or the wire for a touch panel is disposed, a step of performing a pattern exposure on the refractive index adjusting layer formed on the substrate for a touch panel, and a step of developing the refractive index adjusting layer subjected to the pattern exposure to obtain a cured film which protects at least a part of at least one of the electrode for a touch panel or the wire for a touch panel.

[First Peeling Step]

In a case where the transfer film according to the embodiment of the present invention has a protective film, the manufacturing method of a touch panel preferably includes a first peeling step of peeling off the protective film from the transfer film according to the embodiment of the present invention.

The first peeling step is a step of peeling off the protective film from the above-described transfer film according to the embodiment of the present invention, and a peeling method is not particularly limited and a known method can be appropriately adopted.

[Transfer Step]

A transfer step is a step of forming (transferring) the refractive index adjusting layer formed of the composition according to the embodiment of the present invention or obtained by drying the composition on a surface of the substrate for a touch panel on a side where at least one of the electrode for a touch panel or the wire for a touch panel is disposed.

In a case where the transfer film has the photosensitive resin layer between the refractive index adjusting layer and the temporary support, it is preferable that the refractive index adjusting layer and the photosensitive resin layer are simultaneously formed (transferred) by the transfer step.

Examples of a transfer method include a method of laminating the above-described transfer film according to the embodiment of the present invention on the surface of the substrate for a touch panel on the side where at least one of the electrode for a touch panel or the wire for a touch panel is disposed, and transferring the refractive index adjusting layer in the transfer film onto the surface to form the refractive index adjusting layer on the surface.

The laminating (so-called transfer of the refractive index adjusting layer) can be performed using a known laminator such as a vacuum laminator or an auto-cut laminator.

As a laminating condition, a general condition can be applied.

A laminating temperature is preferably 80° C. to 150° C., more preferably 90° C. to 150° C., and still more preferably 100° C. to 150° C.

In a case of using a laminator including a rubber roller, the laminating temperature indicates a temperature of the rubber roller.

A temperature of the substrate in a case of laminating is not particularly limited.

The temperature of the substrate in a case of laminating is preferably 10° C. to 150° C., more preferably 20° C. to 150° C., and still more preferably 30° C. to 150° C.

In a case of using a resin substrate as the substrate, the temperature of the substrate in a case of laminating is preferably 10° C. to 80° C., more preferably 20° C. to 60° C., and still more preferably 30° C. to 50° C.

In addition, a linear pressure in a case of laminating is preferably 0.5 N/cm to 20 N/cm, more preferably 1 N/cm to 10 N/cm, and still more preferably 1 N/cm to 5 N/cm.

In addition, a transportation speed (laminating speed) in a case of laminating is preferably 0.5 m/min to 5 m/min and more preferably 1.5 m/min to 3 m/min.

By the transfer step, the refractive index adjusting layer of the transfer film is transferred onto the surface of the substrate for a touch panel on the side where the electrode and the like of the substrate for a touch panel are arranged, and a laminate having a laminated structure of temporary support/refractive index adjusting layer/electrode and the like/substrate is formed. Alternatively, in a case where the transfer film has the thermoplastic resin layer between the refractive index adjusting layer and the temporary support, a laminate having a laminated structure of temporary support/thermoplastic resin layer/refractive index adjusting layer/electrode and the like/substrate is formed. Alternatively, in a case where the transfer film has the photosensitive resin layer between the refractive index adjusting layer and the temporary support, a laminate having a laminated structure of temporary support/photosensitive resin layer/refractive index adjusting layer/electrode and the like/substrate is formed.

In these laminated structures, the portion of “electrode and the like/substrate” is the substrate for a touch panel.

[Exposure Step]

An exposure step is a step of performing a pattern exposure of the refractive index adjusting layer formed on the substrate for a touch panel.

In a case where the transfer film has the photosensitive resin layer between the refractive index adjusting layer and the temporary support, it is preferable that the refractive index adjusting layer and the photosensitive resin layer are simultaneously subjected to the pattern exposure by the exposure step.

The “pattern exposure” refers to exposure of the aspect of performing the exposure in a patterned manner, that is, the embodiment in which an exposed portion and an unexposed portion are present.

The exposed portion of the refractive index adjusting layer on the substrate for a touch panel in the pattern exposure is cured and finally becomes the cured film.

Meanwhile, the unexposed portion of the refractive index adjusting layer on the substrate for a touch panel in the pattern exposure is not cured, and is dissolved and removed with a developer in the subsequent development step. With the unexposed portion, the opening portion of the cured film can be formed after the development step.

The pattern exposure may be an exposure through a mask or may be a digital exposure using a laser or the like.

As a light source of the pattern exposure, a light source can be appropriately selected, as long as it can emit light at a wavelength region (for example, 365 nm or 405 nm) at which the refractive index adjusting layer can be cured.

Examples of the light source include various lasers, a light emitting diode (LED), an ultra-high pressure mercury lamp, a high pressure mercury lamp, and a metal halide lamp.

An exposure amount is preferably 5 mJ/cm² to 200 mJ/cm² and more preferably 10 mJ/cm² to 200 mJ/cm².

[Second Peeling Step]

The manufacturing method of a touch panel preferably includes a second peeling step of peeling off the temporary support after the exposure step to obtain a laminate in which the cured film is laminated on the substrate having an electrode.

The second peeling step is a step of peeling off the temporary support after the exposure step, and a peeling method is not particularly limited and a known method can be appropriately adopted.

[Development Step]

A development step is preferably performed after the second peeling step.

The development step is a step of developing the refractive index adjusting layer exposed in a patterned manner to obtain a cured film (protective film for a touch panel) which protects at least a part of at least one of the electrode for a touch panel or the wire for a touch panel.

In a case where the transfer film has the photosensitive resin layer between the refractive index adjusting layer and the temporary support, it is preferable that the refractive index adjusting layer exposed in a patterned manner and the photosensitive resin layer exposed in a patterned manner are simultaneously developed by the development step.

A developer used in the development is not particularly limited, and a well-known developer such as a developer disclosed in JP1993-72724A (JP-H5-72724A) can be used.

As the developer, an alkali aqueous solution is preferably used.

Examples of an alkali compound which can be included in the alkali aqueous solution include sodium hydroxide, potassium hydroxide, sodium carbonate, potassium carbonate, sodium hydrogen carbonate, potassium hydrogencarbonate, tetramethyl ammonium hydroxide, tetraethyl ammonium hydroxide, tetrapropyl ammonium hydroxide, tetrabutylammonium hydroxide, and choline (2-hydroxyethyltrimethylammonium hydroxide).

The pH of the alkali aqueous solution at 25° C. is preferably 8 to 13, more preferably 9 to 12, and particularly preferably 10 to 12.

The content of the alkali compound in the alkali aqueous solution is preferably 0.1% by mass to 5% by mass and more preferably 0.1% by mass to 3% by mass with respect to the total mass of the alkali aqueous solution.

The developer may include an organic solvent having miscibility with water.

Examples of the organic solvent include methanol, ethanol, 2-propanol, 1-propanol, butanol, diacetone alcohol, ethylene glycol monomethyl ether, ethylene glycol monoethyl ether, ethylene glycol mono-n-butyl ether, benzyl alcohol, acetone, methyl ethyl ketone, cyclohexanone, ε-caprolactone, γ-butyrolactone, dimethylformamide, dimethylacetamide, hexamethylphosphoramide, ethyl lactate, methyl lactate, ε-caprolactam, and N-methylpyrrolidone.

A concentration of the organic solvent is preferably 0.1% by mass to 30% by mass.

The developer may include a known surfactant.

A concentration of the surfactant is preferably 0.01% by mass to 10% by mass.

A liquid temperature of the developer is preferably 20° C. to 40° C.

Examples of a development method include methods such as puddle development, shower development, shower and spin development, and dip development.

In a case of the shower development, the unexposed portion of the refractive index adjusting layer is removed by spraying the developer to the refractive index adjusting layer after the pattern exposure as a shower.

In a case of using the transfer film including the refractive index adjusting layer (and any photosensitive resin layer) and at least one of the thermoplastic resin layer or the interlayer, after the transfer of these layers onto the substrate and before the development of the refractive index adjusting layer (and the photosensitive resin layer), at least one of the thermoplastic resin layer or the interlayer (in a case where both are present, both) may be removed in advance by spraying an alkali solution having a low solubility in the refractive index adjusting layer (and the photosensitive resin layer) as a shower.

In addition, after the development, the development residue is preferably removed by spraying a washing agent with a shower and rubbing with a brush or the like.

A liquid temperature of the developer is preferably 20° C. to 40° C.

The development step may include a stage of performing the development, and a stage of performing the heat treatment (hereinafter, also referred to as “post baking”) with respect to the cured film obtained by the development.

In a case where the substrate is a resin substrate, a temperature of the post baking is preferably 100° C. to 160° C. and more preferably 130° C. to 160° C.

A resistance value of the transparent electrode pattern can also be adjusted by this post baking.

In a case where the refractive index adjusting layer or the photosensitive resin layer includes a carboxy group-containing (meth)acrylic resin, at least a part of the carboxy group-containing (meth)acrylic resin can be changed to carboxylic acid anhydride by the post baking. In a case of being changed in this way, developability and hardness of the cured film are excellent.

The development step may include a stage of performing the development, and a stage of exposing the cured film obtained by the development (hereinafter, also referred to as “post exposure”).

In a case where the development step includes both a stage of performing the post exposure and a stage of performing the post baking, it is preferable to perform the post-baking after the post-exposure.

With regard to the pattern exposure and the development, for example, a description described in paragraphs 0035 to 0051 of JP2006-23696A can be referred to.

The manufacturing method of a touch panel according to the embodiment of the present disclosure may include a step (so-called other steps) other than the steps described above.

Examples of the other step include a known step (for example, washing step) which may be provided in a normal photolithography step.

### EXAMPLES

Hereinafter, the present disclosure will be described more specifically with reference to Examples. The material, the amount used, the ratio, the process contents, the process procedure, and the like shown in the following examples can be appropriately changed, within a range not departing from a gist of the present disclosure. Accordingly, the range of the disclosure is not limited to specific examples shown below. “part” and “%” are based on mass, unless otherwise specified.

In the following examples, a weight-average molecular weight of a resin is a weight-average molecular weight obtained by performing polystyrene conversion of a value measured by gel permeation chromatography (GPC). In addition, a theoretical acid value is used for the acid value.

### Example 1

[Preparation of Composition]

A coating liquid for a refractive index adjusting layer according to the following formulation 201 was prepared as a composition of Example 1.

Here, the composition of Example 1 was prepared using metal oxide particles, a binder polymer having an acid group, an ammonia aqueous solution, an amine compound, and a mixed solvent of methanol and distilled water, and the binder polymer having an acid group was neutralized with the ammonia aqueous solution and the amine compound to prepare the coating liquid for a refractive index adjusting layer which was an aqueous resin composition including an ammonia salt and amine compound salt of the binder polymer having an acid group.

—Coating Liquid for Refractive Index Adjusting Layer: Formulation 201 (Aqueous Resin Composition)—
Metal oxide particles (ZrO₂ particles, NanoUse OZ-S30M, solid content: 30.5%, methanol 69.5, refractive index: 2.2, average particle diameter: approximately 12 nm, manufactured by Nissan Chemical Corporation): 80.00 parts (solid content)
Binder polymer having acid group (acrylic resin, ZB-015M, manufactured by FUJIFILM Fine Chemicals Co., Ltd., copolymer resin of methacrylic acid/allyl methacrylate, weight-average molecular weight: 25,000, compositional ratio (molar ratio)=20/80, solid content: 5.00%, ammonia aqueous solution): 12.85 parts (solid content)
Binder polymer having acid group (acrylic resin, ARUFON UC3920, manufactured by Toagosei Co., Ltd.): 0.47 parts
Ethylenically unsaturated compound (polyfunctional ethylenically unsaturated compound having a carboxylic acid group, ARONIX TO-2349, manufactured by Toagosei Co., Ltd.): 2.00 parts
Compound having 6-membered heterocyclic structure (adenine, manufactured by Tokyo Chemical Industry Co., Ltd.): 2.00 parts
Surfactant (fluorine-based surfactant, MEGAFACE F-444, manufactured by DIC Corporation): 0.68 parts
Amine compound (N-1, N-methyldiethanolamine, manufactured by Tokyo Chemical Industry Co., Ltd.): 2.00 parts
Solvent: mixed solvent of 7:3 (mass ratio) of methanol and distilled water was added so that the concentration of solid contents of the coating liquid for the refractive index adjusting layer was 1.66% by mass

[Production of Transfer Film]

<Formation of Photosensitive Resin Layer>

On a polyethylene terephthalate film (temporary support, 16QS62, manufactured by Toray Industries, Inc.) having a thickness of 16 μm, a coating liquid for a photosensitive resin layer according to the following formulation 101 was applied using a slit-shaped nozzle such that the thickness after drying was adjusted to 5.5 μm, and the solvent was removed by drying the coating liquid with a hot air convection dryer having a temperature gradient of 75° C. to 120° C. to form a photosensitive resin layer.

—Coating Liquid for Photosensitive Resin Layer: Formulation 101 (Organic Solvent-Based Resin Composition)—

Ethylenically Unsaturated Compound

A-NOD-N (M-1, 1,9-nonanediol diacrylate, manufactured by Shin-Nakamura Chemical Co., Ltd.): 2.73 parts

A-DCP (M-2, tricyclodecanedimethanol diacrylate, manufactured by Shin-Nakamura Chemical Co., Ltd.): 17.90 parts

ARONIX TO-2349 (M-3, polyfunctional ethylenically unsaturated compound having a carboxylic acid group, manufactured by Toagosei Co., Ltd.): 2.98 parts

DPHA (M-4, dipentaerythritol hexaacrylate, manufactured by Toshin Yushi Co., Ltd.): 7.99 parts

Binder Polymer

P-1 (resin shown below, constitutional unit derived from styrene (St)/constitutional unit derived from dicyclopentanyl methacrylate (DCPMA)/constitutional unit derived from methacrylic acid (MAA)/constitutional unit obtained by adding glycidyl methacrylate to a constitutional unit derived from methacrylic acid (GMA-MAA)=41.0/15.2/23.9/19.9 (mol %), Mw=17,000): 52.67 parts (solid content)

Photopolymerization Initiator

1-[9-ethyl-6-(2-methylbenzoyl)-9H-carbazole-3-yl]ethanone-1-(O-acetyloxime) (D-1, Irgacure OXE-02, manufactured by BASF SE): 0.36 parts

2-methyl-1-(4-methylthiophenyl)-2-morpholinopropan-1-one (D-2, Irgacure 907, manufactured by BASF SE): 0.73 parts

Thermal Crosslinking Compound

DURANATE WT32-B75P (E-3, blocked isocyanate compound, manufactured by Asahi Kasei Corporation): 12.50 parts

Compound A-1

Isonicotinamide: 0.52 parts

Compound A-2

Benzimidazole: 0.13 parts

Other Additives

Hydrogen donating compound (AD-1, N-phenylglycine, manufactured by JUNSEI CHEMICAL CO., LTD.): 0.10 parts

Copolymer of styrene/maleic acid anhydride=4:1 (molar ratio) (AD-2, SMA EF-40, acid anhydride value: 1.94 mmol/g, weight-average molecular weight: 10,500, manufactured by Cray Valley): 1.20 parts

Surfactant (AD-3, fluorine-based surfactant, MEGAFACE F-551A, manufactured by DIC Corporation): 0.19 parts
Organic solvent: mixed solvent of 1:1 (mass ratio) of 1-methoxy-2-propyl acetate and methyl ethyl ketone was added so that the concentration of solid contents of the coating liquid for forming a photosensitive resin layer was 25% by mass

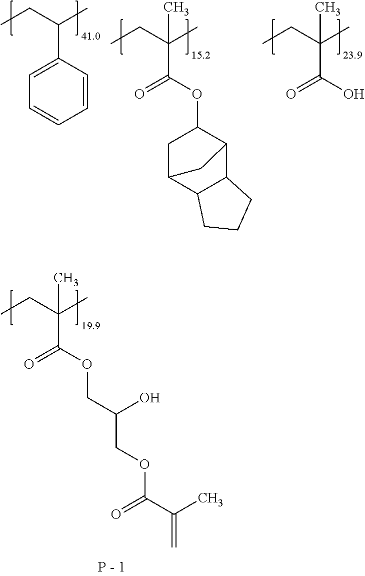

<Formation of Refractive Index Adjusting Layer>

Next, on the above-described photosensitive resin layer, the composition of Example 1 (coating liquid for a refractive index adjusting layer according to the above-described formulation 201) was applied using a slit-shaped nozzle such that the thickness after drying was adjusted to 70 nm, and the solvent was removed by drying the coating liquid with a hot air convection dryer having a temperature gradient of 40° C. to 95° C. to form a refractive index adjusting layer which was disposed to be directly adjacent to the photosensitive resin layer. A refractive index of the refractive index adjusting layer was 1.68 at a wavelength of 550 nm at 25° C.

<Formation of Protective Film>

For a laminate obtained as described above, in which the photosensitive resin layer and the refractive index adjusting layer which was disposed to be directly adjacent to the photosensitive resin layer were provided on the temporary support in this order, a polyethylene terephthalate film (protective film, 16QS62, manufactured by Toray Industries, Inc.) having a thickness of 16 μm was pressure-bonded onto the refractive index adjusting layer to produce a transfer film of Example 1.

### Examples 2 to 6 and 8 to 18, and Comparative Examples 1 to 3

A transfer film was produced in the same manner as in Example 1, except that the formulation of the composition used as the refractive index adjusting layer was changed as shown in Table 1 below. Although the solvent is omitted in Table 1, the solvent and concentration of solid contents of the compositions of each Examples and Comparative Examples are the same as those of the composition of Example 1.

### Example 7

A composition of Example 7 shown in Table 1 below was prepared. In the composition of Example 7, 0.58 parts of OXE-01 (product name: IRGACURE (registered trademark) OXE-01, manufactured by BASF SE) was added as the photopolymerization initiator. Although the solvent is omitted in Table 1, the solvent and concentration of solid contents of the composition of Example 7 are the same as the organic solvent and concentration of solid contents of the coating liquid for a photosensitive resin layer according to the formulation 101.

On a polyethylene terephthalate film (temporary support, 16QS62, manufactured by Toray Industries, Inc.) having a thickness of 16 μm, the composition (coating liquid for a refractive index adjusting layer) of Example 7 was applied using a slit-shaped nozzle such that the thickness after drying was adjusted to 4.0 μm, and the solvent was removed by drying the coating liquid with a hot air convection dryer having a temperature gradient of 75° C. to 120° C. to form a single-layer refractive index adjusting layer.

For a laminate obtained as described above, in which the single-layer refractive index adjusting layer directly adjacent to the temporary support was provided, a polypropylene film (protective film, ALPHAN E-201F, manufactured by Oji F-Tex Co., Ltd.) having a thickness of 30 μm was pressure-bonded onto the single-layer refractive index adjusting layer to produce a transfer film of Example 7.

### Example 16

—Coating Liquid for Photosensitive Resin Layer: Formulation 102 (Organic Solvent-Based Resin Composition)—

Ethylenically Unsaturated Compound

A-NOD-N (M-1, 1,9-nonanediol diacrylate, manufactured by Shin-Nakamura Chemical Co., Ltd.): 2.79 parts

A-DCP (M-2, tricyclodecanedimethanol diacrylate, manufactured by Shin-Nakamura Chemical Co., Ltd.): 9.13 parts

ARONIX TO-2349 (M-3, polyfunctional ethylenically unsaturated compound having a carboxylic acid group, manufactured by Toagosei Co., Ltd.): 3.04 parts

DPHA (M-4, dipentaerythritol hexaacrylate, manufactured by Toshin Yushi Co., Ltd.): 1.73 parts

Binder Polymer

P-2 (resin shown below, constitutional unit derived from styrene (St)/constitutional unit derived from methacrylic acid (MAA)/constitutional unit obtained by adding glycidyl methacrylate to a constitutional unit derived from methacrylic acid (GMA-MAA)/constitutional unit of methyl methacrylate (MMA)=55.1/26.5/16.9/1.5 (mol %), Mw=17,000): 49.04 parts (solid content)

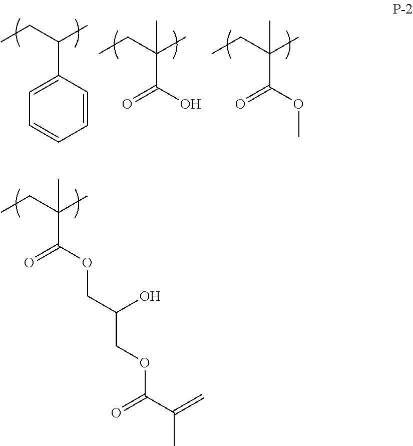

Photopolymerization Initiator

1-[9-ethyl-6-(2-methylbenzoyl)-9H-carbazole-3-yl]ethanone-1-(O-acetyloxime) (D-1, Irgacure OXE-02, manufactured by BASF SE): 0.37 parts

2-methyl-1-(4-methylthiophenyl)-2-morpholinopropan-1-one (D-2, Irgacure 907, manufactured by BASF SE): 0.74 parts

Thermal Crosslinking Compound

DURANATE WT32-B75P (blocked isocyanate compound, manufactured by Asahi Kasei Corporation): 12.50 parts

Compound having following structure: 3.00 parts

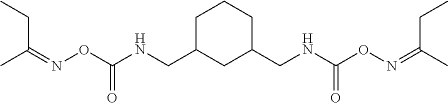 [SMILES: CC/C(C)=N\OC(=O)NCC1CCCC(CNC(=O)O/N=C(/C)CC)C1]

Compound A-1

Isonicotinamide: 0.52 parts

Compound A-2

Benzimidazole: 0.13 parts

Other Additives

Hydrogen donating compound (AD-1, N-phenylglycine, manufactured by JUNSEI CHEMICAL CO., LTD.): 0.10 parts

Copolymer of styrene/maleic acid anhydride=4:1 (molar ratio) (AD-2, SMA EF-40, acid anhydride value: 1.94 mmol/g, weight-average molecular weight: 10,500, manufactured by Cray Valley): 1.20 parts

Surfactant (AD-3, fluorine-based surfactant, MEGAFACE F-551A, manufactured by DIC Corporation): 0.19 parts
Organic solvent: mixed solvent of 1:1 (mass ratio) of 1-methoxy-2-propyl acetate and methyl ethyl ketone was added so that the concentration of solid contents of the coating liquid for forming a photosensitive resin layer was 25% by mass

[Production of Transfer Film]

<Formation of Photosensitive Resin Layer>

On a polyethylene terephthalate film (temporary support, 16QS62, manufactured by Toray Industries, Inc.) having a thickness of 16 μm, a coating liquid for a photosensitive resin layer according to the following formulation 102 was applied using a slit-shaped nozzle such that the thickness after drying was adjusted to 5.5 μm, and the solvent was removed by drying the coating liquid with a hot air convection dryer having a temperature gradient of 75° C. to 120° C. to form a photosensitive resin layer.

<Formation of Refractive Index Adjusting Layer>

Next, on the above-described photosensitive resin layer, the composition of Example 1 (coating liquid for a refractive index adjusting layer according to the above-described formulation 201) was applied using a slit-shaped nozzle such that the thickness after drying was adjusted to 70 nm, and the solvent was removed by drying the coating liquid with a hot air convection dryer having a temperature gradient of 40° C. to 95° C. to form a refractive index adjusting layer which was disposed to be directly adjacent to the photosensitive resin layer. A refractive index of the refractive index adjusting layer was 1.68 at a wavelength of 550 nm at 25° C.

<Formation of Protective Film>

For a laminate obtained as described above, in which the photosensitive resin layer and the refractive index adjusting layer which was disposed to be directly adjacent to the photosensitive resin layer were provided on the temporary support in this order, a polyethylene terephthalate film (protective film, 16QS62, manufactured by Toray Industries, Inc.) having a thickness of 16 μm was pressure-bonded onto the refractive index adjusting layer to produce a transfer film of Example 16.

### Example 17

A transfer film was produced in the same manner as in Example 16, except that the thickness of the photosensitive resin layer after drying was adjusted to 4.5 μm.

### Example 18

A transfer film was produced in the same manner as in Example 16, except that the thickness of the photosensitive resin layer after drying was adjusted to 8.8 μm.

The structure of the amine compound used in each Examples is as follows. In Table 1 below, the linking chain length (maximum value) of the linking group included in the substituent on the nitrogen atom in each amine compound and the weight-average molecular weight of each amine compound are shown.

N-1: N-methyldiethanolamine

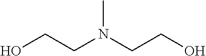

N-2: 3-(Diethylamino)-1,2-propanediol

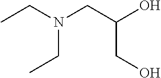

N-3: 2-[2-(Dimethylamino)ethoxy]ethanol

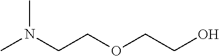

N-4: N,N,N′,N′-tetrakis(2-hydroxypropyl)ethylenediamine

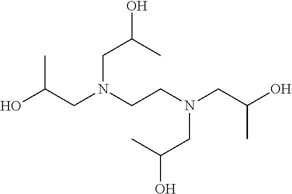 [SMILES: CC(O)CN(CCN(CC(C)O)CC(C)O)CC(C)O]

The structure of the amine compound used in each Comparative Examples is as follows.

N-5: Isopropanolamine

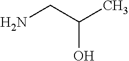

N-6 Diisopropylamine

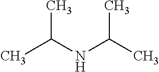

Metal oxide particles used in Example 11 and the ethylenically unsaturated compound used in Example 12 are as follows.
Metal oxide particles (titanium dioxide particles, TS-020, containing tin oxide and silicon dioxide, non-volatile content: 25.8%, manufactured by Tayca Corporation)
Ethylenically unsaturated compound (2-hydroxyethyl methacrylate, LIGHT ESTER HO-250(N), manufactured by KYOEISHA CHEMICAL Co., LTD.)

[Evaluation]

The obtained transfer film was used and evaluated as follows. The obtained results are shown in Table 1 below.

[Evaluation of Bendability]

With regard to the obtained transfer film, from above the protective film, the entire surface was exposed through the protective film using a proximity type exposure machine (manufactured by Hitachi High-Tech Electronics Engineering Co., Ltd.) including an ultra-high pressure mercury lamp with an exposure amount of 120 mJ/cm² (i ray).

Thereafter, the protective film was peeled off, and the temporary support was wound 180° around a rod having a diameter of 1 mm and allowed to stand for 5 minutes.

Thereafter, the surface of the refractive index adjusting layer was observed using an optical microscope to confirm the presence or absence of cracks.

In the following evaluation standard, A was the best bendability and D was the worst.

A or B was preferable, and A was more preferable.

A: no cracks had occurred.

B: there was a slight crack.

C: there was a crack on the entire surface.

D: the entire surface was cracked, and the resin layer was peeled off in some places.

[Evaluation of Rust Preventive Property]

After peeling off the protective film, the obtained photosensitive transfer material was laminated on a copper plate from the refractive index adjusting layer. In the laminating conditions, a laminating roll temperature was set as 100° C., a linear pressure was set as 3 N/cm, and a transportation speed was set as 4 m/min.

Thereafter, with regard to the obtained laminate before exposure, using a proximity type exposure machine (manufactured by Hitachi High-Tech Electronics Engineering Co., Ltd.) including an ultra-high pressure mercury lamp, a distance between a surface of an exposure mask (1 mm wide line and space pattern; 5 lines) and the temporary support was set to 125 μm, and pattern exposure was performed through the temporary support with an exposure amount of 120 mJ/cm² (i ray). After peeling off the temporary support, the laminate after pattern exposure was immersed in a 1% aqueous solution of sodium carbonate at 33° C. and allowed to stand for 45 seconds for development treatment. After the development treatment, the residue was removed by injecting ultrapure water from an ultrapure water washing nozzle onto the copper substrate. Subsequently, air was blown to remove moisture on the copper substrate, and post-baking treatment was performed at 140° C. for 30 minutes to obtain a sample for evaluating rust preventive property.

Thereafter, the above-described sample for evaluating rust preventive property was allowed to stand in an environment of 85° C. and a relative humidity of 85% RH for 24 hours.

Discoloration of copper in a space portion of this pattern was visually confirmed.

In the following evaluation standard, A was the best rust preventive property and D was the worst. Any one of A, B, or C was preferable, A or B was more preferable, and A was particularly preferable.

A: same as the color of copper before treatment, no discoloration at all

B: slightly discolored red

C: discolored red

D: discolored blue

TABLE 1-1

| | | Linking chain length | | | | | | | | | | | | |
|---|---|---|---|---|---|---|---|---|---|---|---|---|---|---|
| | | (maximum value) of | | | | | | | | | | | | |
| | | linking group | | | | | | | | | | | | |
| | | included in | | | | | | | | | | | | |
| | | substituent of | Molecular | Example | | | | | | | Comparative example | | | |
| | | nitrogen atom | weight | 1 | 2 | 3 | 4 | 5 | 6 | 7 | 1 | 2 | 3 | |
| Metal oxide particles | NanoUse OZ-S30M | — | — | 80.00 | 80.00 | 80.00 | 80.00 | 80.00 | 80.00 | 50.00 | 80.00 | 80.00 | 80.00 | |
| | TS-020 | — | — | | | | | | | | | | | |
| Binder polymer having acid group | ZB-015M | — | — | 12.85 | 12.85 | 12.85 | 12.85 | 12.85 | 12.85 | 27.85 | 12.85 | 12.85 | 16.85 | |
| | UC3920 | — | — | 0.47 | 0.47 | 0.47 | 0.47 | 0.47 | 0.47 | 0.47 | 0.47 | 0.47 | 0.47 | |
| Ethylenically unsaturated | TO-2349 | — | — | 2.00 | 2.00 | 2.00 | 2.00 | 2.00 | 2.00 | 17.00 | 2.00 | 2.00 | 2.00 | |
| compound | LIGHT ESTER HO-250 (N) | | | | | | | | | | | | | |
| Photopolymerization initiator | OXE-01 | — | — | — | — | — | — | — | — | 0.58 | — | — | — | |
| Compound having 6-membered | Adenine | — | — | 2.00 | 2.00 | 2.00 | 2.00 | | | 2.00 | 2.00 | 2.00 | | |
| heterocyclic structure | Pyrimidine | — | — | | | | | 2.00 | | | | | | |
| Surfactant | F-444 | — | — | 0.68 | 0.68 | 0.68 | 0.68 | 0.68 | 0.68 | 0.68 | 0.68 | 0.68 | 0.68 | |
| Amine compound | N-1 | 3 | 119 | 2.00 | | | | 2.00 | | 2.00 | | | | |
| | N-2 | 4 | 147 | | 2.00 | | | | 2.00 | | | | | |
| | N-3 | 6 | 133 | | | 2.00 | | | | | | | | |
| | N-4 | 3 | 292 | | | | 2.00 | | | | | | | |
| | N-5 | 3 | 75 | | | | | | | | 2.00 | | | |
| | N-6 | 2 | 101 | | | | | | | | | 2.00 | | |
| Refractive index | | | | 1.68 | 1.68 | 1.68 | 1.68 | 1.68 | 1.68 | 1.62 | 1.68 | 1.68 | 1.68 | |
| Film thickness (nm) | | | | 70 | 70 | 70 | 70 | 70 | 70 | 4.0 × 10³ | 70 | 70 | 70 | |
| Photosensitive resin layer | Presence or absence | — | — | Presence | Presence | Presence | Presence | Presence | Presence | Absence | Presence | Presence | Presence | |
| | Formulation | — | | 101 | 101 | 101 | 101 | 101 | 101 | — | 101 | 101 | 101 | |
| | Thickness (μm) | — | | 5.5 | 5.5 | 5.5 | 5.5 | 5.5 | 5.5 | — | 5.5 | 5.5 | 5.5 | |
| Evaluation | Bendability | — | — | A | A | A | B | A | A | A | c | c | D | |
| | Rust prevention property | — | — | A | A | A | A | A | B | A | A | c | D | |
| | | Linking chain length | | | | | | | | | | | | |
| | | (maximum value) of | | | | | | | | | | | | |
| | | linking group | | | | | | | | | | | | |
| | | included in | | | | | | | | | | | | |
| | | substituent of | Molecular | Example | | | | | | | Comparative example | | | |
| | | nitrogen atom | weight | 8 | 9 | 10 | 11 | 12 | 13 | 14 | 15 | 16 | 17 | 18 |
| Metal oxide particles | NanoUse OZ-S30M | — | — | 80.00 | 80.00 | 85.00 | | 80.00 | 80.00 | 80.00 | 80.00 | 80.00 | 80.00 | 80.00 |
| | TS-020 | — | — | | | | 57.50 | | | | | | | |
| Binder polymer having acid group | ZB-015M | — | — | 13.85 | 10.35 | 7.85 | 35.35 | 12.85 | 14.85 | 12.85 | 12.85 | 12.85 | 12.85 | 12.85 |
| | UC3920 | — | — | 0.47 | 0.47 | 0.47 | 0.47 | 0.47 | 0.47 | 0.47 | 0.47 | 0.47 | 0.47 | 0.47 |
| Ethylenically unsaturated | TO-2349 | — | — | 2.00 | 2.00 | 2.00 | 2.00 | | | 2.00 | 2.00 | 2.00 | 2.00 | 2.00 |
| compound | LIGHT ESTER HO-250 (N) | | | | | | | 2.00 | | | | | | |
| Photopolymerization initiator | OXE-01 | — | — | — | — | — | — | — | — | — | — | — | — | — |
| Compound having 6-membered | Adenine | — | — | 2.00 | 2.00 | 2.00 | 2.00 | 2.00 | 2.00 | 2.00 | 2.00 | 2.00 | 2.00 | 2.00 |
| heterocyclic structure | Pyrimidine | — | — | | | | | | | | | | | |
| Surfactant | F-444 | — | — | 0.68 | 0.68 | 0.68 | 0.68 | 0.68 | 0.68 | 0.68 | 0.68 | 0.68 | 0.68 | 0.68 |
| Amine compound | N-1 | 3 | 119 | 1.00 | 4.50 | 2.00 | 2.00 | 2.00 | 2.00 | 2.00 | 2.00 | 2.00 | 2.00 | 2.00 |
| | N-2 | 4 | 147 | | | | | | | | | | | |
| | N-3 | 6 | 133 | | | | | | | | | | | |
| | N-4 | 3 | 292 | | | | | | | | | | | |
| | N-5 | 3 | 75 | | | | | | | | | | | |
| | N-6 | 2 | 101 | | | | | | | | | | | |
| Refractive index | | | | 1.68 | 1.68 | 1.69 | 1.69 | 1.68 | 1.68 | 1.68 | 1.68 | 1.68 | 1.68 | 1.68 |
| Film thickness (nm) | | | | 70 | 70 | 70 | 70 | 70 | 70 | 50 | 100 | 70 | 70 | 70 |
| Photosensitive resin layer | Presence or absence | — | — | Presence | Presence | Presence | Presence | Presence | Presence | Presence | Presence | Presence | Presence | Presence |
| | Formulation | — | | 101 | 101 | 101 | 101 | 101 | 101 | 101 | 101 | 102 | 102 | 102 |
| | Thickness (μm) | — | — | 5.5 | 5.5 | 5.5 | 5.5 | 5.5 | 5.5 | 5.5 | 5.5 | 5.5 | 4.5 | 8.8 |
| Evaluation | Bendability | — | — | A | A | A | A | A | A | A | A | A | A | A |
| | Rust prevention property | — | — | A | A | A | A | A | A | A | A | A | A | A |

From the results shown in Table 1, by using the composition according to the embodiment of the present invention, it was found that a transfer film having improved bendability was obtained in a case of having a layer including metal oxide particles.

From Comparative Example 1, in a case where the weight-average molecular weight of the amine compound was lower than the lower limit specified in the present invention, it was found that the bendability was inferior.

From Comparative Example 2, in a case where the linking chain length of the linking group included in the substituent on the nitrogen atom in the amine compound was lower than the lower limit specified in the present invention, it was found that the bendability was inferior.

From Comparative Example 3, in a case where the amine compound was not contained, it was found that the bendability was inferior.

According to Examples 1 to 18, which were preferred aspects of the composition according to the embodiment of the present invention, it was found that a transfer film having further improved rust preventive property could be provided.

### Examples 101 to 106 and 108 to 118

[Production of Display Device]

A substrate in which a second refractive index adjusting layer, an ITO transparent electrode pattern, and copper lead wire were formed on a cycloolefin transparent film was prepared.

Using each of the transfer films Examples 1 to 6 and 8 to 18 from which the protective film was peeled off, the second refractive index adjusting layer, the ITO transparent electrode pattern, and the copper lead wire were laminated at a position covered by the transfer film. The laminating was performed using a vacuum laminator manufactured by MCK under conditions of a cycloolefin transparent film temperature: 40° C., a rubber roller temperature: 100° C., a linear pressure: 3 N/cm, and a transportation speed: 2 m/min.

Thereafter, using a proximity type exposure machine (manufactured by Hitachi High-Tech Electronics Engineering Co., Ltd.) including an ultra-high pressure mercury lamp, a surface of an exposure mask (quartz exposure mask having a pattern for forming an overcoat) and the temporary support were closely attached, and the laminate was exposed in a patterned shape with an exposure amount of 100 mJ/cm² (i ray) through the temporary support.

After peeling off the temporary support, the laminate after pattern exposure was immersed in a 1% aqueous solution of sodium carbonate at 33° C. and allowed to stand for 45 seconds for development treatment.

Thereafter, the residue was removed by injecting ultrapure water from an ultrapure water washing nozzle onto the transparent film substrate after the development treatment. Subsequently, air was blown to remove water on the transparent film substrate, and post-baking treatment was performed at 145° C. for 30 minutes to form a transparent laminate in which the second refractive index adjusting layer, the ITO transparent electrode pattern, the copper lead wire, the cured film (cured product of the refractive index adjusting layer), and the cured product of the photosensitive resin layer were laminated in this order on the transparent film substrate.

[Production of Display Device]

Using the produced transparent laminate, an electrostatic capacity-type touch panel member (input device) was produced by a known method.

The produced touch panel member was attached to a liquid crystal display element produced by a method described in paragraphs 0097 to 0119 of JP2009-047936A, thereby producing a touch panel including the touch panel member as an input device and a liquid crystal display device as a display device.

### Example 107

A transparent laminate in which the second refractive index adjusting layer, the ITO transparent electrode pattern, the copper lead wire, and the cured film (cured product of the single-layer refractive index adjusting layer) were laminated in this order on the transparent film substrate was formed in the same manner as in Example 101, except that the transfer film of Example 7 was used instead of the transfer film of Example 1.

[Evaluation of Touch Panel]

It was confirmed that the touch panels of each Examples had excellent display properties and operated without problems.

### EXPLANATION OF REFERENCES

10: transfer film
12: temporary support
16: protective film
18: electrode protective film for touch panel
18A: photosensitive resin layer
20: first refractive index adjusting layer
20A: refractive index adjusting layer
30: touch panel
32: substrate
34: transparent electrode pattern
36: second refractive index adjusting layer
40: first region where transparent electrode pattern is present
42: second region where transparent electrode pattern is not present
56: lead wire
70: first transparent electrode pattern
72: second transparent electrode pattern
74: image display region
75: image non-display region
90: touch panel

What is claimed is:

1. A composition comprising:
an amine compound;
metal oxide particles; and
a binder polymer having an acid group,
wherein the amine compound has, as a substituent on a nitrogen atom in the amine compound, a substituent which includes a linking group having a linking chain length of 3 or more, and
a weight-average molecular weight of the amine compound is 100 or more.

2. The composition according to claim 1,
wherein the amine compound is a compound represented by General Formula N, 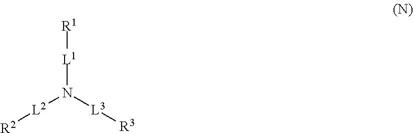
in General Formula N, L¹ represents a linking group having a linking chain length of 3 or more and including an oxygen atom, and R¹ represents a hydrogen atom or a halogen atom, and
L² and L³ each independently represent an alkylene group or a linking group having a linking chain length of 3 or more and including an oxygen atom, and R² and R³ each independently represent a hydrogen atom or a halogen atom.

3. The composition according to claim 1,
wherein a content of the metal oxide particles is 40% to 95% by mass with respect to a total solid content of the composition.

4. The composition according to claim 1,
wherein the metal oxide particles include at least one type selected from the group consisting of zirconium oxide particles and titanium oxide particles.

5. The composition according to claim 1, further comprising:
a compound having a 6-membered heterocyclic structure,
wherein the compound having a 6-membered heterocyclic structure has a monocyclic or polycyclic aromatic heterocyclic ring structure.

6. The composition according to claim 5,
wherein the compound having a 6-membered heterocyclic structure has a 6-membered heterocyclic structure having two nitrogen atoms in the ring structure.

7. The composition according to claim 5,
wherein the compound having a 6-membered heterocyclic structure is adenine or pyrimidine.

8. The composition according to claim 1, further comprising:
an ethylenically unsaturated compound.

9. The composition according to claim 8, further comprising:
a photopolymerization initiator.

10. The composition according to claim 1, further comprising:
a compound having a 6-membered heterocyclic structure and an ethylenically unsaturated compound,
wherein the compound having a 6-membered heterocyclic structure has a monocyclic or polycyclic aromatic heterocyclic ring structure,
the amine compound is a compound represented by General Formula N, and
the metal oxide particles include at least one type selected from the group consisting of zirconium oxide particles and titanium oxide particles, 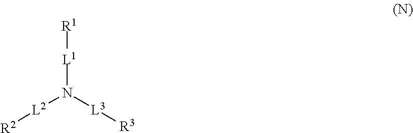
in General Formula N, L¹ represents a linking group having a linking chain length of 3 or more and including an oxygen atom, and R¹ represents a hydrogen atom or a halogen atom, and
L² and L³ each independently represent an alkylene group or a linking group having a linking chain length of 3 or more and including an oxygen atom, and R² and R³ each independently represent a hydrogen atom or a halogen atom.

11. The composition according to claim 1,
wherein the composition is used for forming a protective film in a touch panel.

12. The composition according to claim 1,
wherein the composition is used for forming a refractive index adjusting layer in a touch panel.

13. A producing method of a composition comprising:
preparing a composition using an amine compound, metal oxide particles, and a binder polymer having an acid group,
wherein the amine compound has, as a substituent on a nitrogen atom in the amine compound, a substituent which includes a linking group having a linking chain length of 3 or more, and
a weight-average molecular weight of the amine compound is 100 or more.

14. A cured film of the composition according to claim 1.

15. A cured film of the composition according to claim 10.
